(19) United States
(12) Patent Application Publication
(10) Pub. No.: US 2024/0234570 A1
(43) Pub. Date: Jul. 11, 2024

(54) SEMICONDUCTOR DEVICE, POWER CONVERSION APPARATUS, AND METHOD OF MANUFACTURING SEMICONDUCTOR DEVICE

(71) Applicant: Mitsubishi Electric Corporation, Tokyo (JP)

(72) Inventor: Tetsuo TAKAHASHI, Tokyo (JP)

(73) Assignee: Mitsubishi Electric Corporation, Tokyo (JP)

(21) Appl. No.: 18/510,582

(22) Filed: Nov. 15, 2023

(30) Foreign Application Priority Data
Jan. 6, 2023 (JP) 2023-001092

(51) Int. Cl. H01L 29/78; H01L 29/40; H01L 29/423

(52) U.S. Cl. CPC H01L 29/7813; H01L 29/401; H01L 29/42368

(57) ABSTRACT

A semiconductor device includes a trench formed in a semiconductor layer of an active region, a gate insulating film and a gate electrode formed in the trench, a gate pad formed on a field insulating film, and a gate lead-out wiring line connecting the gate pad and the gate electrode. A shoulder portion, a sidewall portion, and a bottom portion of the trench are covered with the field insulating film in a gate pull-up portion which is an end portion of the trench corresponding to a place where the gate lead-out wiring line and the gate electrode in the trench are connected. The thickness of the field insulating film covering the shoulder portion, the sidewall portion, and the bottom portion of the trench in the gate pull-up portion is equivalent to or larger than the thickness of the field insulating film under the gate pad.

### BACKGROUND OF THE INVENTION

### Field of the Invention

The present disclosure relates to a semiconductor device, particularly, a semiconductor device for power control.

### Description of the Background Art

A semiconductor device for power control generally referred to as a power device is used as a switching element that controls power supply to a load such as a motor. Power devices are required to have several characteristics, and one of the largest requirements is to reduce the loss. The reduction in loss of the power device contributes to the reduction in size and weight of the apparatus, and eventually leads to consideration for the global environment by reducing energy consumption. In addition, it is also important to achieve these characteristics at low cost.

As a semiconductor element used for a power device, an insulated gate semiconductor element such as an insulated gate bipolar transistor (IGBT) or a metal oxide semiconductor field effect transistor (MOSFET) is widely used. As one of structures of an insulated gate semiconductor element, there is a trench type structure in which a gate electrode is embedded in a trench (for example, Japanese Patent Application Laid-Open Nos. 2001-358338, 2001-015733, 2005-197274, 2003-008018, 2009-088188, and 2018-006628, below). The trench-type insulated gate semiconductor element can increase the channel density, and thus can reduce the loss. In addition, in recent years, a MOSFET, an IGBT, or the like using a wide band gap semiconductor such as silicon carbide (SIC) has been proposed (Japanese Patent Application Laid-Open No. 2018-006628).

In a semiconductor device including a trench-type insulated gate semiconductor element, in order to electrically connect a gate electrode embedded in a trench to a gate pad, a gate lead-out wiring line formed by leading out a part of the gate electrode onto a substrate is provided. Hereinafter, the vicinity of the end portion of the trench corresponding to the place where the gate lead-out wiring line and the gate electrode in the trench are connected is referred to as a “gate pull-up portion”. In addition, an upper end portion of the trench, that is, a corner portion at a boundary between the surface of the substrate and the side surface of the trench is referred to as a “trench shoulder portion”.

Since an electric field is concentrated in a trench shoulder portion of the gate pull-up portion when a voltage is applied to the gate electrode, the breakdown of the gate insulating film is likely to occur at that portion. As a countermeasure, in Japanese Patent Application Laid-Open Nos. 2001-358338, 2001-015733, 2005-197274, and 2003-008018, the thickness of the gate insulating film formed in the gate pull-up portion is increased. In addition, in Japanese Patent Application Laid-Open No. 2009-088188, the radius of curvature of the trench shoulder portion of the gate pull-up portion is increased to prevent concentration of the electric field.

An insulated gate semiconductor element using a wide band gap semiconductor such as silicon carbide has a high withstand voltage and can operate at a high speed. However, when a high voltage is controlled at a high speed, the rate of change (dV/dt) of the voltage applied to the semiconductor element increases, and thus, there is a concern that the displacement current increases the potential of the diffusion layer of the substrate facing the insulating film in contact with the vicinity of the gate electrode, and the breakdown of the field insulating film under the gate pad occurs. The increase in the diffusion layer potential of the substrate in the vicinity of the gate electrode causes breakdown of the gate insulating film also at the trench shoulder portion of the gate pull-up portion.

### SUMMARY

An object of the present disclosure is to provide a semiconductor device capable of alleviating an electric field of a trench shoulder portion of a gate pull-up portion and preventing breakdown of an insulating film due to high dV/dt.

A semiconductor device according to the present disclosure includes a semiconductor layer in which an active region in which a semiconductor element is formed and a withstand voltage holding region outside the active region are defined. A trench is formed in the semiconductor layer in the active region. A gate insulating film is formed on an inner surface of the trench. A gate electrode embedded in the trench is provided on the gate insulating film. A field insulating film thicker than the gate insulating film is formed on the semiconductor layer. A gate pad is formed on the field insulating film. The gate pad and the gate electrode are connected by a gate lead-out wiring line. An end portion of the trench corresponding to a place where the gate lead-out wiring line and the gate electrode in the trench are connected is referred to as a gate pull-up portion. In the gate pull-up portion, a shoulder portion, a sidewall portion, and a bottom portion of the trench are covered with the field insulating film, and the gate lead-out wiring line is formed on the field insulating film. A thickness of the field insulating film covering the shoulder portion, the sidewall portion, and the bottom portion of the trench in the gate pull-up portion is equivalent to or larger than a thickness of the field insulating film under the gate pad.

According to the semiconductor device according to the present disclosure, since the thickness of the insulating film covering the shoulder portion, the sidewall portion, and the bottom portion of the trench of the gate pull-up portion is equivalent to or larger than the thickness of the field insulating film, it is possible to obtain an effect of having a high resistance to insulating film breakdown when a gate voltage is applied and preventing insulating film breakdown when a high dV/dt during switching is applied.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a semiconductor device according to a first preferred embodiment;

FIG. 2 is an enlarged plan view of a boundary portion between an active region and a gate pad region of the semiconductor device according to the first preferred embodiment;

FIG. 3 is an enlarged plan view of a boundary portion between an active region and a withstand voltage holding region of the semiconductor device according to the first preferred embodiment;

FIG. 4 is a cross-sectional view taken along line A1-A2 of the semiconductor device according to the first preferred embodiment;

FIG. 5 is a cross-sectional view taken along line B1-B2 of the semiconductor device according to the first preferred embodiment;

FIG. 6 is a cross-sectional view taken along line C1-C2 of the semiconductor device according to the first preferred embodiment;

FIG. 7 is a cross-sectional view taken along line D1-D2 of the semiconductor device according to the first preferred embodiment;

FIG. 8 is a cross-sectional view taken along line E1-E2 of the semiconductor device according to the first preferred embodiment;

FIG. 9 is an explanatory diagram of a manufacturing step of the semiconductor device according to the first preferred embodiment;

FIG. 10 is an explanatory diagram of a manufacturing step of the semiconductor device according to the first preferred embodiment;

FIG. 11 is an explanatory diagram of a manufacturing step of the semiconductor device according to the first preferred embodiment;

FIG. 12 is an explanatory diagram of a manufacturing step of the semiconductor device according to the first preferred embodiment;

FIG. 13 is an explanatory diagram of a manufacturing step of the semiconductor device according to the first preferred embodiment;

FIG. 14 is an explanatory diagram of a manufacturing step of the semiconductor device according to the first preferred embodiment;

FIG. 15 is an explanatory diagram of a manufacturing step of the semiconductor device according to the first preferred embodiment;

FIG. 16 is an explanatory diagram of a manufacturing step of the semiconductor device according to the first preferred embodiment;

FIG. 17 is an explanatory diagram of a manufacturing step of the semiconductor device according to the first preferred embodiment;

FIG. 18 is a cross-sectional view taken along line A1-A2 of a semiconductor device according to a second preferred embodiment;

FIG. 19 is a cross-sectional view taken along line B1-B2 of the semiconductor device according to the second preferred embodiment;

FIG. 20 is a cross-sectional view taken along line C1-C2 of the semiconductor device according to the second preferred embodiment;

FIG. 21 is a cross-sectional view taken along line D1-D2 of the semiconductor device according to the second preferred embodiment;

FIG. 22 is a cross-sectional view taken along line E1-E2 of the semiconductor device according to the second preferred embodiment;

FIG. 23 is an explanatory diagram of a manufacturing step of the semiconductor device according to the second preferred embodiment;

FIG. 24 is an explanatory diagram of a manufacturing step of the semiconductor device according to the second preferred embodiment;

FIG. 25 is an explanatory diagram of a manufacturing step of the semiconductor device according to the second preferred embodiment;

FIG. 26 is an explanatory diagram of a manufacturing step of the semiconductor device according to the second preferred embodiment;

FIG. 27 is a diagram for illustrating points to note regarding the manufacturing step of the semiconductor device according to the second preferred embodiment;

FIG. 28 is a cross-sectional view taken along line A1-A2 of a semiconductor device according to a third preferred embodiment;

FIG. 29 is a cross-sectional view taken along line B1-B2 of the semiconductor device according to the third preferred embodiment;

FIG. 30 is a cross-sectional view taken along line C1-C2 of the semiconductor device according to the third preferred embodiment;

FIG. 31 is a cross-sectional view taken along line D1-D2 of the semiconductor device according to the third preferred embodiment;

FIG. 32 is a cross-sectional view taken along line E1-E2 of the semiconductor device according to the third preferred embodiment;

FIG. 33 is an explanatory diagram of a manufacturing step of the semiconductor device according to the third preferred embodiment;

FIG. 34 is an explanatory diagram of a manufacturing step of the semiconductor device according to the third preferred embodiment;

FIG. 35 is an explanatory diagram of a manufacturing step of the semiconductor device according to the third preferred embodiment;

FIG. 36 is an explanatory diagram of a manufacturing step of the semiconductor device according to the third preferred embodiment;

FIG. 37 is an enlarged plan view of a boundary portion between an active region and a gate pad region of a semiconductor device according to a fourth preferred embodiment;

FIG. 38 is an enlarged plan view of a boundary portion between an active region and a withstand voltage holding region of the semiconductor device according to the fourth preferred embodiment;

FIG. 39 is a cross-sectional view taken along line A1-A2 of the semiconductor device according to the fourth preferred embodiment;

FIG. 40 is a cross-sectional view taken along line F1-F2 of the semiconductor device according to the fourth preferred embodiment;

FIG. 41 is a cross-sectional view taken along line G1-G2 of the semiconductor device according to the fourth preferred embodiment;

FIG. 42 is a cross-sectional view taken along line H1-H2 of the semiconductor device according to the fourth preferred embodiment;

FIG. 43 is a cross-sectional view taken along line I1-I2 of the semiconductor device according to the fourth preferred embodiment; and

FIG. 44 is a block diagram showing a configuration of a power conversion system to which a power conversion apparatus according to a fifth preferred embodiment is applied.

### DESCRIPTION OF THE PREFERRED EMBODIMENTS

### First Preferred Embodiment

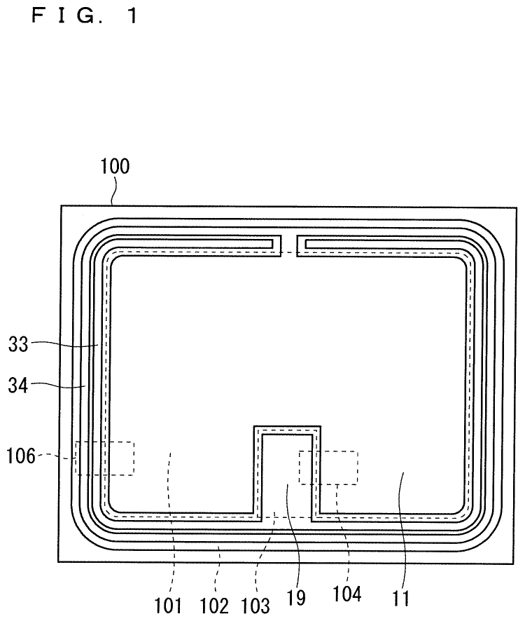

The configuration of the semiconductor device 100 according to a first preferred embodiment will be described with reference to FIGS. 1 to 8. Here, the semiconductor element included in the semiconductor device 100 will be described as a MOSFET. However, the semiconductor element only needs to be a trench-type insulated gate semiconductor element, and may be, for example, an element other than a MOSFET such as an IGBT.

Hereinafter, the first conductivity type is described as n-type and the second conductivity type is described as p-type, but conversely, the first conductivity type may be p-type and the second conductivity type may be n-type. In addition, an n-type having a relatively high impurity concentration is denoted as “n⁺”, an n-type having a relatively low impurity concentration is denoted as “n⁻”, a p-type having a relatively high impurity concentration is denoted as “p⁺”, and a p-type having a relatively low impurity concentration is denoted as “p⁻”. Here, the height of the impurity concentration of each region is defined by the peak concentration. That is, the region having a high (or low) impurity concentration means a region having a high (or low) impurity peak concentration.

FIG. 1 is a plan view of a semiconductor device 100. As shown in FIG. 1, the semiconductor device 100 is divided into an active region 101 in which a MOSFET as a semiconductor element is formed, a withstand voltage holding region 102 provided outside the active region 101, and a gate pad region 103 in which a gate pad 19 is disposed. The gate pad 19 is electrically connected to a gate electrode (not shown in FIG. 1) which is a control electrode of the MOSFET. In the active region 101, a source electrode 11 which is one main electrode of the MOSFET and functions as a source pad is disposed. In addition, in the withstand voltage holding region 102, an outer peripheral gate wiring line 33 connected to the gate pad 19 is disposed, and outside the outer peripheral gate wiring line 33, an outer peripheral source wiring line 34 connected to the source electrode 11 is disposed.

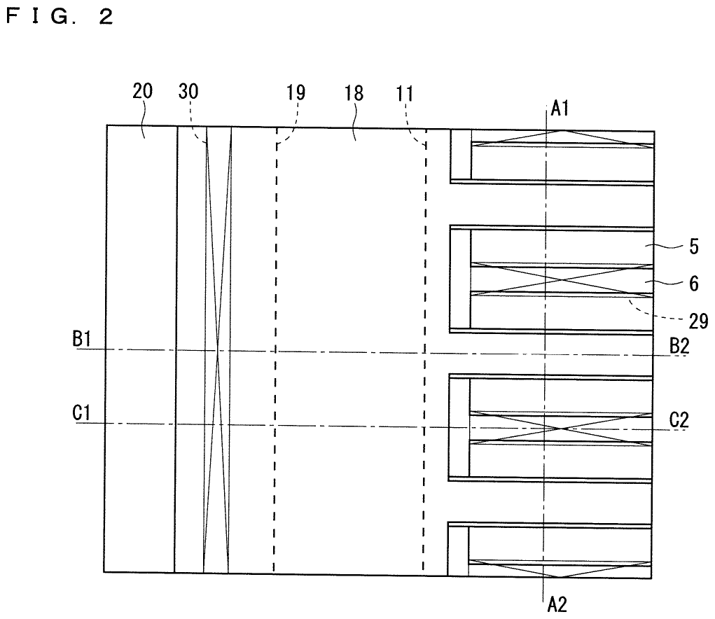

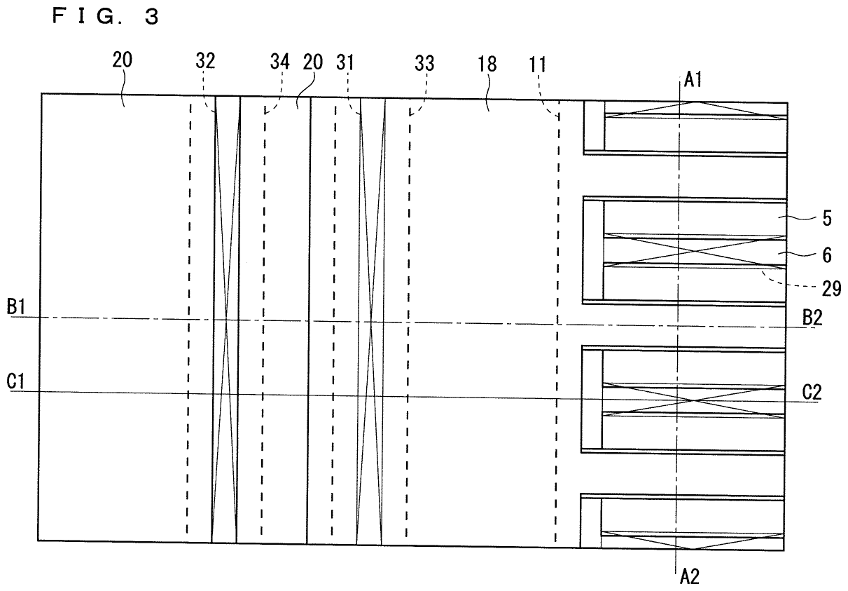

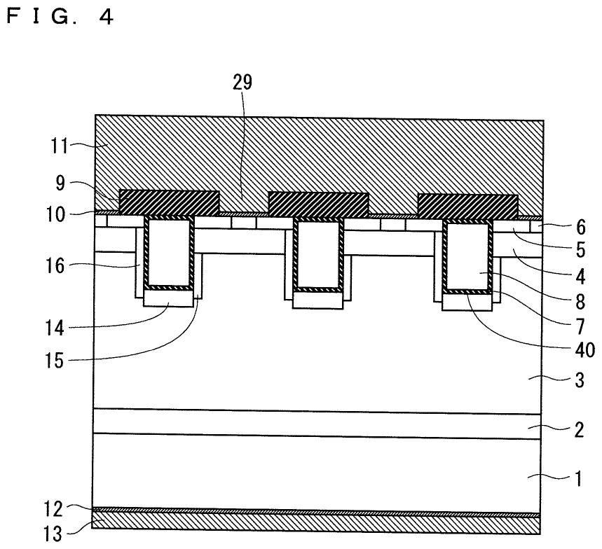

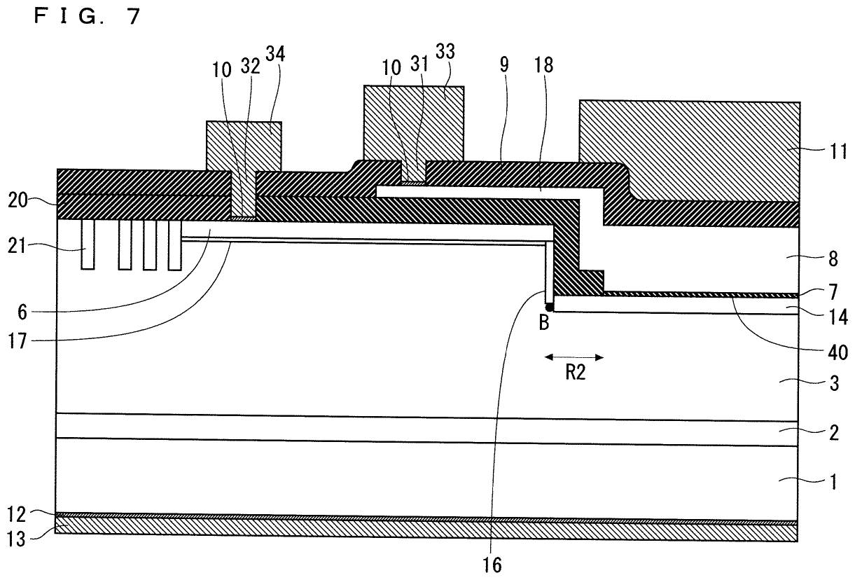

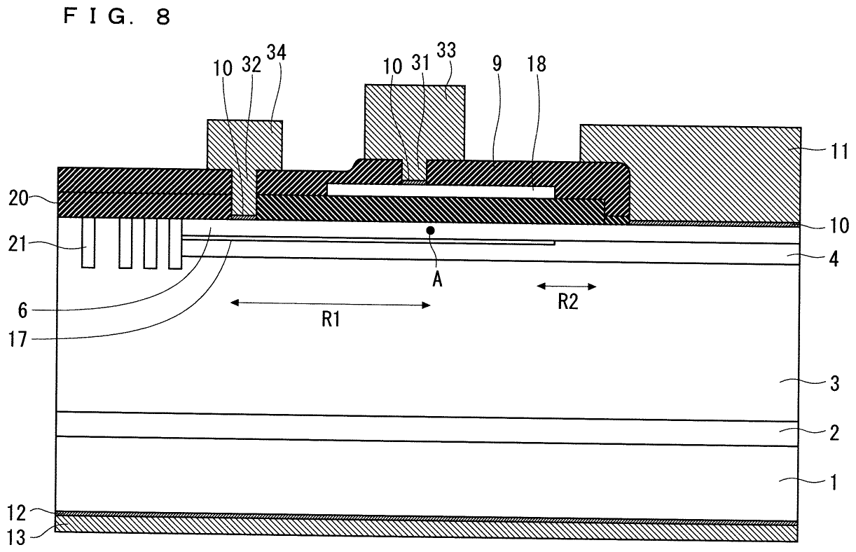

FIG. 2 is an enlarged plan view of a boundary portion 104 between the active region 101 and the gate pad region 103 shown in FIG. 1, and FIG. 3 is an enlarged plan view of a boundary portion 106 between the active region 101 and the withstand voltage holding region 102 shown in FIG. 1. In addition, FIGS. 4, 5, and 6 are cross-sectional views taken along lines A1-A2, B1-B2, and C1-C2 shown in FIG. 2, respectively. FIGS. 7 and 8 are cross-sectional views taken along lines D1-D2 and E1-E2 shown in FIG. 3, respectively. It should be noted that in FIGS. 2 and 3, the source electrode 11, the gate pad 19, the outer peripheral gate wiring line 33, and the outer peripheral source wiring line 34 are indicated by broken lines. In FIGS. 2 and 3, rectangles in which diagonal lines are drawn indicate contact holes.

As shown in FIGS. 4 to 8, the semiconductor device 100 is formed using a semiconductor layer including an n⁺ substrate 1, an n⁺ buffer layer 2 formed on the n⁺ substrate 1, and an n− drift layer 3 formed on the n⁺ buffer layer 2.

In the active region 101, as shown in FIG. 4, a p-channel doped layer 4 is formed in a surface portion of the n⁻ drift layer 3. In addition, each of the n source layer 5 and the p+ contact layer 6 is selectively formed in the surface portion of the p-channel doped layer 4. In addition, on the upper surface of the semiconductor layer, a trench 40 that penetrates the n source layer 5 and the p-channel doped layer 4 to reach the n⁻ drift layer 3 is formed. A gate insulating film 7 is formed on a side wall portion and a bottom portion of the trench 40, and a gate electrode 8 embedded in the trench 40 is formed on the gate insulating film 7. The n− drift layer 3, the p-channel doped layer 4, the n source layer 5, the gate insulating film 7, and the gate electrode 8 constitute a basic structure of the MOSFET.

The gate electrode 8 is covered with an interlayer insulating film 9, and the source electrode 11 is formed on the interlayer insulating film 9. A source contact hole 29 reaching the n source layer 5 and the p⁺ contact layer 6 is formed in the interlayer insulating film 9, and the source electrode 11 is electrically connected to the n source layer 5 and the p⁺ contact layer 6 through the source contact hole 29. In the present preferred embodiment, source electrode 11 is connected to the n source layer 5 and the p⁺ contact layer 6 through the silicide layer 10 formed at the bottom of the source contact hole 29.

On the lower surface of the n+ substrate 1, a drain electrode 13 which is another main electrode of the MOSFET is formed. The drain electrode 13 is electrically connected to the n+ substrate 1. In the present preferred embodiment, the drain electrode 13 is connected to the n⁺ substrate 1 through the silicide layer 12 formed on the lower surface of the n⁺ substrate 1.

A trench bottom portion p-type layer 14 that alleviates an electric field generated at the bottom portion of the trench 40 is formed in a surface portion of the semiconductor layer at the bottom portion of the trench 40. In addition, a trench sidewall n-type layer 15 is formed on a part of the sidewall of the trench 40, and a trench sidewall p-type layer 16 is formed on the other part of the sidewall of the trench 40. The trench sidewall p-type layer 16 electrically connects the trench bottom portion p-type layer 14 to the source electrode 11 by connecting between the trench bottom portion p-type layer 14 and the p-channel doped layer 4. The trench sidewall n-type layer 15 prevents the current path between the trenches 40 from being narrowed by the trench bottom portion p-type layer 14, and contributes to reduction of the on-resistance of the MOSFET.

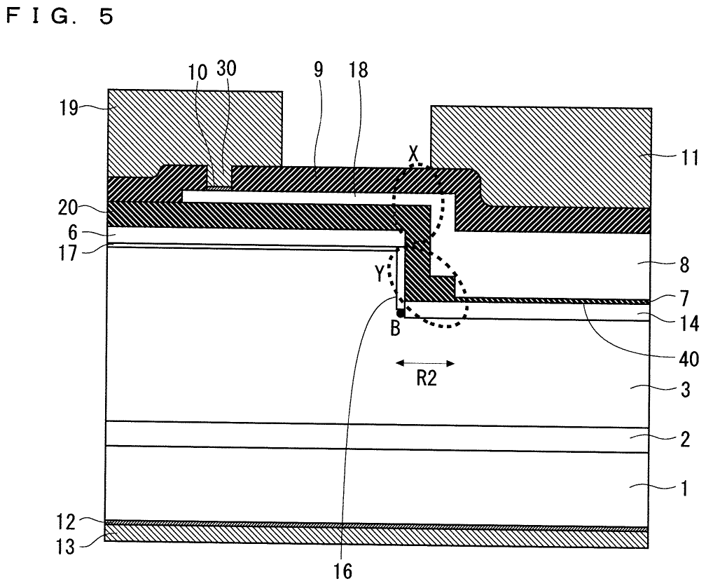

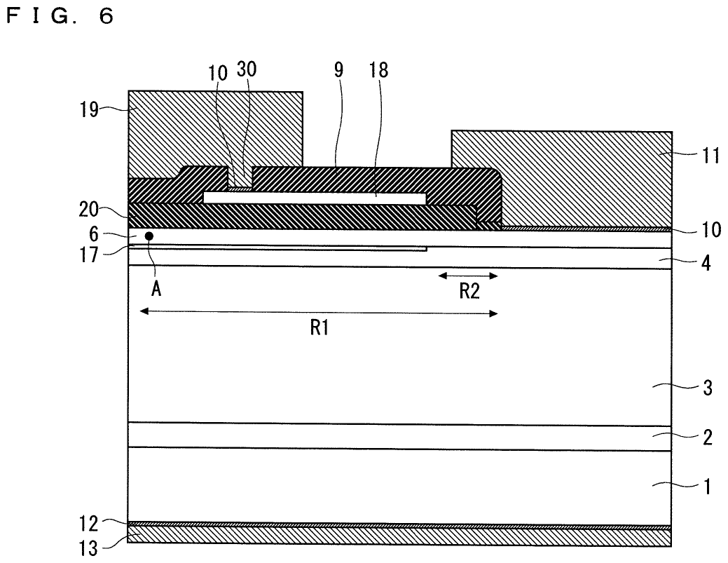

In the gate pad region 103, as shown in FIGS. 5 and 6, an under gate pad p-type layer 17 is formed in a surface portion of the n⁻ drift layer 3 under the gate pad 19. A p⁺contact layer 6 similar to that of the active region 101 is formed in a surface portion of the under gate pad p-type layer 17. In addition, the upper surface of the semiconductor layer is covered with a field insulating film 20 thicker than the gate insulating film 7, and a gate lead-out wiring line 18 formed by leading out a part of the gate electrode 8 to the upper surface of the semiconductor layer is provided on the field insulating film 20. Similarly to the gate electrode 8, the gate lead-out wiring line 18 is covered with the interlayer insulating film 9, and the gate pad 19 is formed on the interlayer insulating film 9. A gate contact hole 30 reaching the gate lead-out wiring line 18 is formed in the interlayer insulating film 9 under the gate pad 19, and the gate pad 19 is electrically connected to the gate lead-out wiring line 18 through the gate contact hole 30. In the present preferred embodiment, the gate pad 19 is connected to the gate lead-out wiring line 18 through the silicide layer 10 formed at the bottom portion of the gate contact hole 30.

As shown in FIGS. 7 and 8, the p-channel doped layer 4, the under gate pad p-type layer 17, the p⁺ contact layer 6, the field insulating film 20, the gate lead-out wiring line 18, and the interlayer insulating film 9 extend to the withstand voltage holding region 102. In addition, on the outer side of the p-channel doped layer 4, the under gate pad p-type layer 17, and the p⁺ contact layer 6, an outer peripheral p-type diffusion layer 21 is formed in the surface portion of the n⁺ buffer layer 2. The outer peripheral p-type diffusion layer 21 includes a plurality of ring-shaped regions and constitutes a withstand voltage holding structure referred to as field limiting ring (FLR).

The outer peripheral gate wiring line 33 and the outer peripheral source wiring line 34 are formed on the interlayer insulating film 9 in the withstand voltage holding region 102. An outer peripheral gate contact hole 31 reaching the gate lead-out wiring line 18 is formed in the interlayer insulating film 9 under the outer peripheral gate wiring line 33, and the outer peripheral gate wiring line 33 is electrically connected to the gate lead-out wiring line 18 through the outer peripheral gate contact hole 31. In addition, an outer peripheral source contact hole 32 reaching the p⁺ contact layer 6 is formed in the interlayer insulating film 9 and the field insulating film 20 under the outer peripheral source wiring line 34, and the outer peripheral source wiring line 34 is electrically connected to the p⁺ contact layer 6 through the outer peripheral source contact hole 32. In the present preferred embodiment, the outer peripheral gate wiring line 33 is connected to the gate lead-out wiring line 18 through the silicide layer 10 formed at the bottom portion of the outer peripheral gate contact hole 31, and the outer peripheral source wiring line 34 is connected to the p+ contact layer 6 through the silicide layer 10 formed at the bottom portion of the outer peripheral source contact hole 32.

In the present preferred embodiment, the material of the semiconductor layer including the n⁺ substrate 1, the n⁺ buffer layer 2, the n⁻ drift layer 3, and the like is silicon carbide (SiC), the material of the gate electrode 8 is polysilicon, and the material of the source electrode 11 and the drain electrode 13 is metal containing aluminum. However, these materials are not limited thereto. For example, the material of the semiconductor layer may be a wide bandgap semiconductor other than SiC, such as gallium nitride (GaN) or diamond, in addition to silicon (Si).

The semiconductor device 100 according to the first preferred embodiment has the following features. A first feature is that, at an end portion of the trench 40 corresponding to a place where the gate lead-out wiring line 18 and the gate electrode 8 in the trench 40 are connected, that is, at a gate pull-up portion, a shoulder portion (region X shown in FIG. 5) of the trench 40 is covered with an insulating film thicker than the gate insulating film 7. A second feature is that, in the gate pull-up portion, the side wall portion and the bottom portion (region Y shown in FIG. 5) of the trench 40 are covered with an insulating film thicker than the gate insulating film 7. A third feature is that the thick insulating film is an insulating film formed simultaneously with the field insulating film 20 (In other words, the thick insulating film is a part of the field insulating film 20).

A fourth feature is that, when a resistance value between a point (point A shown in FIGS. 6 and 8) farthest from a place (that is, a position of the source contact hole 29 or the outer peripheral source contact hole 32 which is a contact place of the source electrode 11 with respect to the p-type diffusion layer) to which the source potential is applied in the p-type diffusion layer (that is, the p-channel doped layer 4, the under gate pad p-type layer 17, and the p+ contact layer 6) immediately below the gate pad 19 or the outer peripheral gate wiring line 33 and a place to which the source potential is applied is R1, and a resistance value between an end portion (point B in FIGS. 5 and 7) of the p-type diffusion layer (that is, the trench bottom portion p-type layer 14) immediately below the trench 40 in the gate pull-up portion and a position to which the source potential is applied is R2, R1 is R2 or more, that is, R1≥R2 holds.

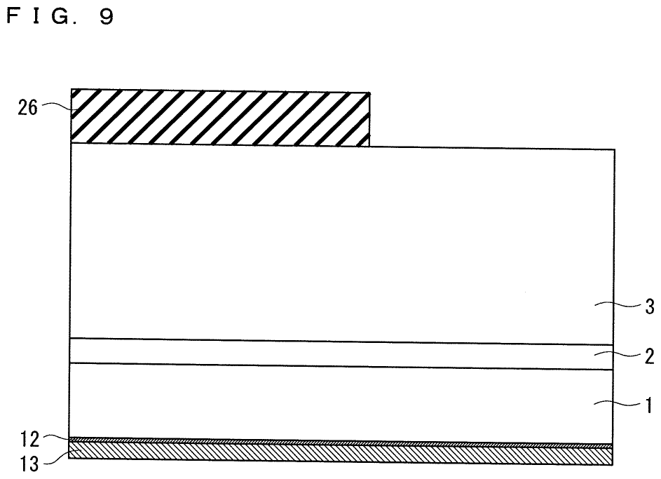

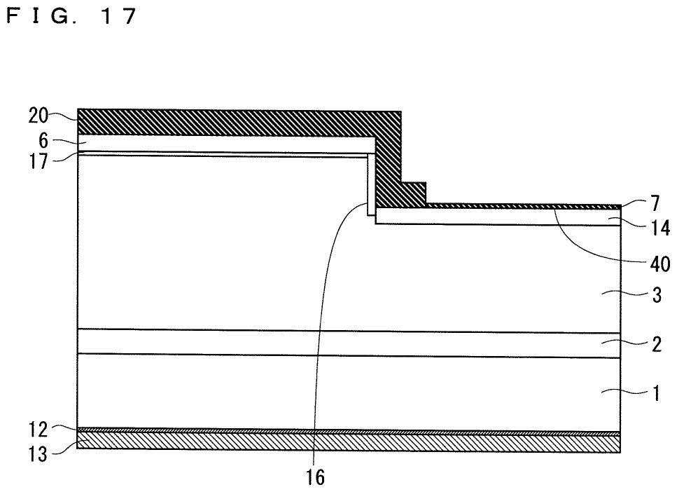

Next, a method of manufacturing the semiconductor device 100 according to the first preferred embodiment will be described. FIGS. 9 to 17 are explanatory diagrams of the manufacturing step of the semiconductor device 100 according to the first preferred embodiment, and each correspond to the cross section shown in FIG. 5 (cross section taken along line B1-B2 in FIG. 2).

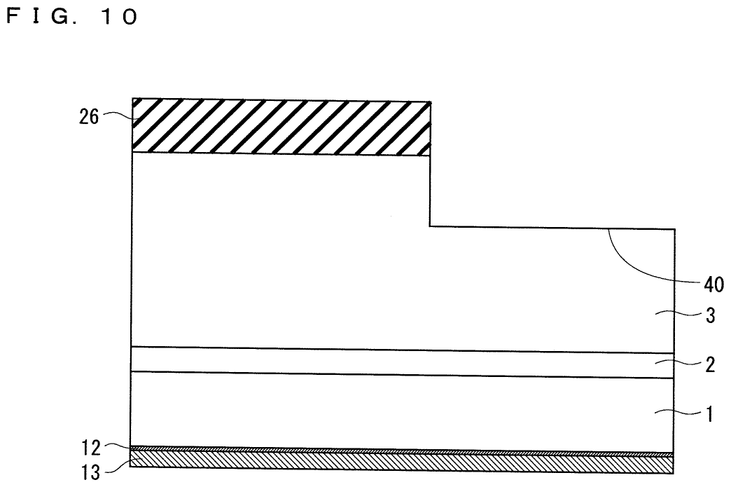

First, an n⁺ buffer layer 2 and an n− drift layer 3 are formed on an n⁺ substrate 1, and a mask material 26 in which a formation region of a trench 40 is opened is formed on a semiconductor layer including the n⁺ buffer layer 2 and the n⁻ drift layer 3 by using a photolithography technique or the like (FIG. 9). The mask material 26 may be a photoresist, a plasma insulating film selectively formed using a photoresist or the like, or the like. Then, a trench 40 is formed in the semiconductor layer by etching using the mask material 26 (FIG. 10).

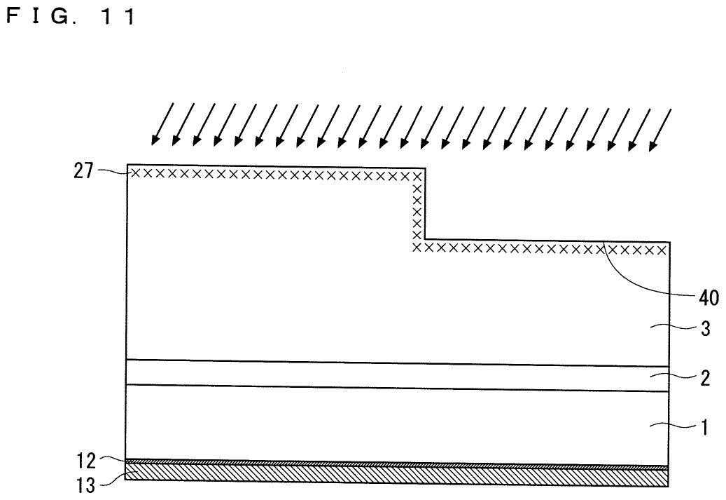

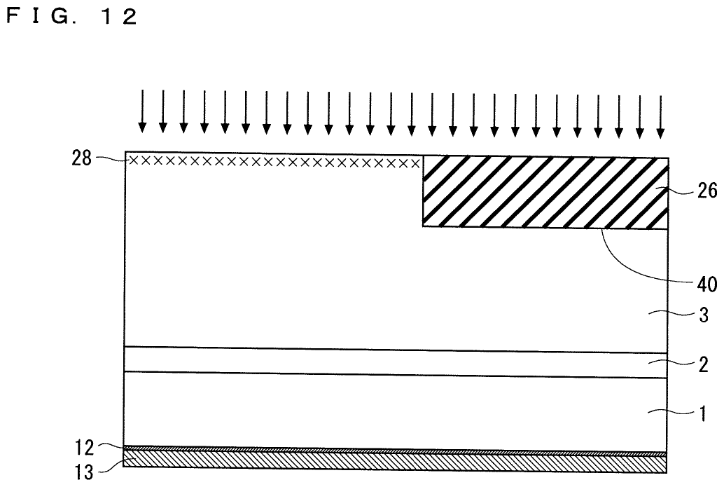

Subsequently, by introducing impurities into the semiconductor layer using a photolithography technique or an ion implantation technique, various impurity regions such as the p-channel doped layer 4, the n source layer 5, the p⁺ contact layer 6, the trench bottom portion p-type layer 14, and the under gate pad p-type layer 17 are formed. When impurities are ion-implanted into the sidewall portion of the trench 40, ions are implanted obliquely into the surface of the semiconductor layer (FIG. 11). In addition, when it is not desired to introduce impurities, ion implantation is appropriately performed after the mask material 26 is formed in the place (FIG. 12). It should be noted that FIG. 11 shows an example in which the impurity introduction layer 27 is formed in the surface portion of the n− drift layer 3 and the sidewall portion and the bottom portion of the trench 40 by ion implantation from an oblique direction, and FIG. 12 shows an example in which the impurity introduction layer 28 is formed in the upper layer portion of the n− drift layer 3 outside the trench 40 by performing ion implantation in a state where the mask material 26 is formed in the trench 40.

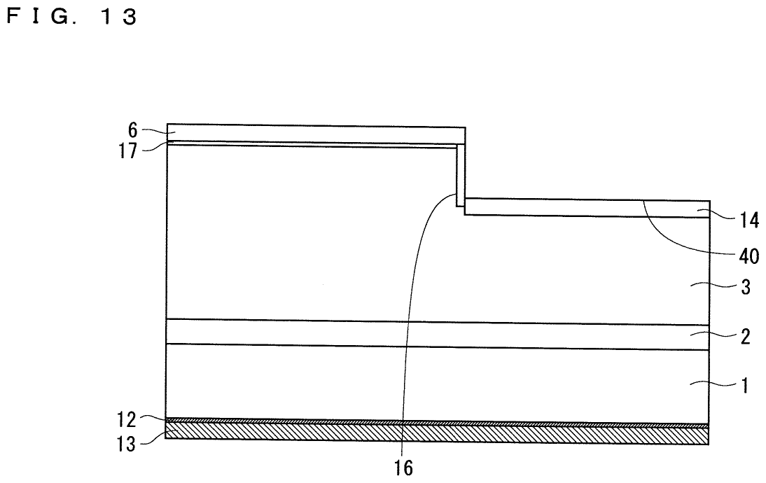

Thereafter, the semiconductor layer is subjected to heat treatment to diffuse and activate the impurities implanted into the semiconductor layer (FIG. 13). This heat treatment may be performed after all the ion implantation of the impurities is completed, or the ion implantation of the impurities and the heat treatment may be alternately repeated.

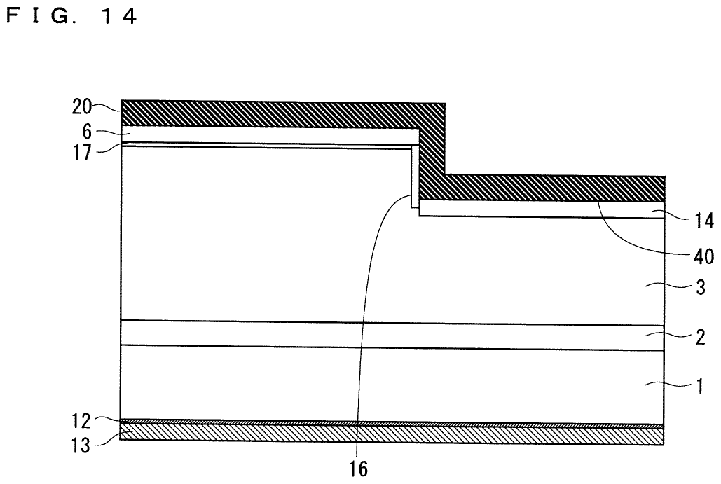

Subsequently, a field insulating film 20 is formed on the upper surface of the semiconductor layer (FIG. 14). The field insulating film 20 can be formed by a thermal oxidation method or a deposition method. The thickness of the field insulating film 20 to be formed is determined in consideration of the loss of the field insulating film 20 in a cleaning step, an etching step, or the like to be performed later.

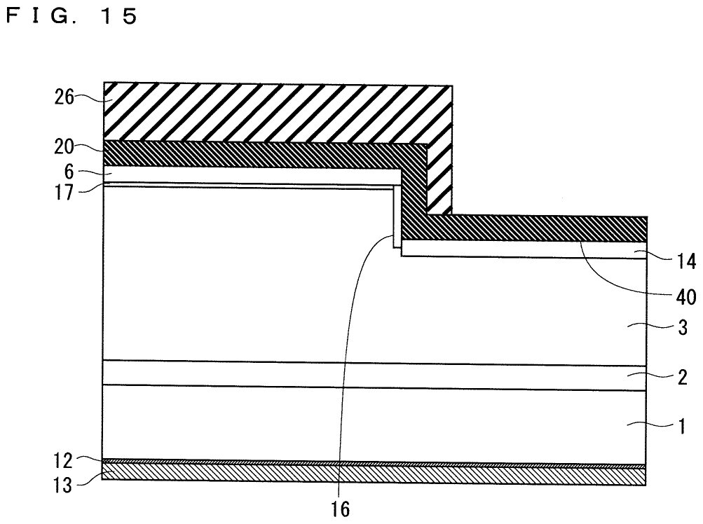

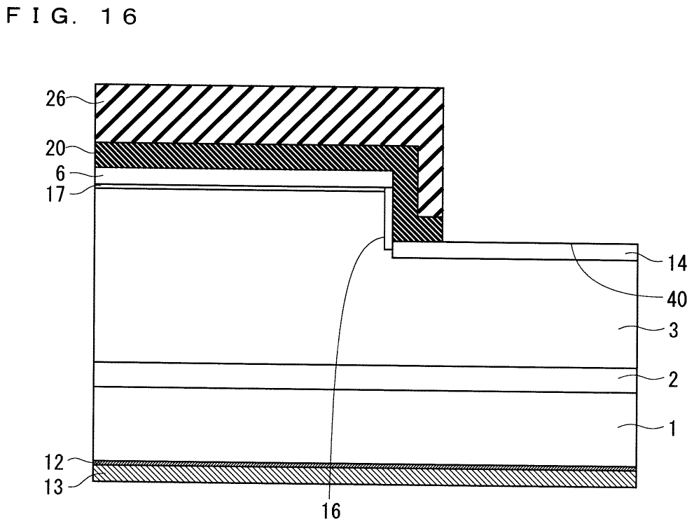

Next, using a photolithography technique, a mask material 26 is formed so as to cover the withstand voltage holding region 102, the gate pad region 103, and the gate pull-up portion (FIG. 15), and the field insulating film 20 is etched (FIG. 16). Accordingly, the field insulating film 20 remains as an insulating film thicker than the gate insulating film 7 in the withstand voltage holding region 102, the gate pad region 103, and the gate pull-up portion. In addition, the field insulating film 20 is removed from a portion other than the gate pull-up portion in the trench 40.

Thereafter, the mask material 26 is removed, and the gate insulating film 7 is formed in the sidewall portion and the bottom portion of the trench 40 by a thermal oxidation method or a deposition method. As a result, a structure is obtained in which a gate insulating film 7 is formed in the sidewall portion and the bottom portion of the trench 40 in the active region 101 excluding the gate pull-up portion, and an insulating film (field insulating film 20) thicker than the gate insulating film 7 is formed in the shoulder portion, the sidewall portion, and the bottom portion of the trench 40 in the gate pull-up portion. That is, a structure having the first to third features described above is obtained.

Thereafter, a forming step of the gate electrode 8 (including the gate lead-out wiring line 18), the interlayer insulating film 9, the silicide layer 10, the source electrode 11, the gate pad 19, the outer peripheral gate wiring line 33, the outer peripheral source wiring line 34, the drain electrode 13, and the like is performed. Since these steps may be the same as those in a general semiconductor manufacturing technique, the description thereof will be omitted.

Next, the operation of the semiconductor device 100 according to the first preferred embodiment will be described. When a voltage equal to or higher than the threshold voltage of the MOSFET is applied to the gate electrode 8 through the gate pad 19, a channel is formed in the p-channel doped layer 4 adjacent to the gate electrode 8, and conduction is established between the source electrode 11 and the drain electrode 13, so that the voltage of the drain electrode 13 decreases, a main current flows between the source electrode 11 and the drain electrode 13, and the MOSFET is turned on.

Conversely, when the voltage of the gate electrode 8 becomes less than the threshold voltage in the on state, the channel of the p-channel doped layer 4 disappears, the current path between the source electrode 11 and the drain electrode 13 is cut off, the drain voltage rises, and the MOSFET is turned off.

Here, since the gate electrode 8, the gate lead-out wiring line 18, the gate pad 19, and the outer peripheral gate wiring line 33 are connected by a member having low resistivity, when a voltage is applied to the gate electrode 8, they basically have the same potential. Therefore, a shoulder portion (region X in FIG. 5) of the trench 40 of the gate pull-up portion also has the same voltage. However, since a gate voltage is two-dimensionally applied from the upper, lower, left, and right sides to a shoulder portion of the trench 40 of the gate pull-up portion and a high electric field is generated, the shoulder portion is a place where the gate insulating film is deteriorated and is likely to be broken.

In the semiconductor device 100 according to the first preferred embodiment, since the shoulder portion of the trench 40 of the gate pull-up portion is covered with the field insulating film 20 which is an insulating film thicker than the gate insulating film 7, the electric field of the shoulder portion is relaxed, and the occurrence of the insulating film breakdown at the shoulder portion is prevented. In particular, in the first preferred embodiment, the insulating film covering the shoulder portion of the trench 40 of the gate pull-up portion is a part of the field insulating film 20. Therefore, as shown in FIGS. 5 and 7, the thickness of the insulating film covering the shoulder portion of the trench 40 of the gate pull-up portion is equivalent to the thickness of the field insulating film 20 under the gate pad 19. In addition, the field insulating film 20 formed on the gate pull-up portion has a stepped shape with a step on the upper surface in a cross-sectional view. It should be noted that “the same”, “equivalent”, and the like used in the present specification do not need to be completely the same, and include substantially the same. That is, variations in the manufacturing step and differences in the degree of error are allowed.

Normally, the field insulating film 20 is formed in the withstand voltage holding region 102 and the gate pad region 103, and the thickness thereof is designed to a thickness to the extent of not causing a problem in consideration of stabilization of the withstand voltage of the withstand voltage holding region 102 and the like in addition to prevention of insulating film breakdown at the time of applying a gate voltage. In the present preferred embodiment, the shoulder portion of the trench 40 of the gate pull-up portion is covered with the insulating film having the same thickness as the field insulating film 20 designed with such a thickness, and the characteristics equivalent to those of the field insulating film 20 can be obtained with respect to the insulating film breakdown at the shoulder portion.

Furthermore, the field insulating film 20 is designed to have a thickness to the extent of not causing malfunction due to an instantaneous voltage increase or the like, insulating film breakdown, and the like at the time of switching. When a high dV/dt is generated between the source and the drain at the time of switching, a displacement current flows in the p-type diffusion layer under the gate pad 19. Therefore, the voltage of the p-type diffusion layer under the gate pad 19 and the outer peripheral gate wiring line 33 increases depending on the resistance value of the p-type diffusion layer. In principle, this voltage tends to be higher at a position farther from a place grounded to the source potential in the p-type diffusion layer, and is highest near the point A shown in FIGS. 6 and 8.

This problem also occurs in the gate pull-up portion shown in FIGS. 5 and 7, and in the p-type diffusion layer (point B shown in FIGS. 5 and 7) of the gate pull-up portion positioned far from the source potential, a voltage increase due to dV/dt is likely to occur. However, in the semiconductor device according to the first preferred embodiment, since the resistance value R1 from the point A under the gate pad 19 or the outer peripheral gate wiring line 33 to the position grounded to the closest source potential and the resistance value R2 from the point B at the end portion of the trench 40 of the gate pull-up portion to the position grounded to the closest source potential are designed to have a relationship of R1≥R2, an increase in voltage at the gate pull-up portion is suppressed. Element breakdown due to insulating film breakdown is prevented in a gate pull-up portion that is covered with the field insulating film 20 designed to have a thickness to the extent of not causing a problem with respect to voltage increase due to a displacement current when dV/dt is high and is designed to suppress voltage increase due to a displacement current at the time of dV/dt.

As described above, in the first preferred embodiment, since the thickness of the insulating film covering the shoulder portion, the sidewall portion, and the bottom portion, of the trench 40 of the gate pull-up portion is made equivalent to the thickness of the field insulating film 20, it is possible to obtain the effect of having a high resistance with respect to insulating film breakdown when a gate voltage is applied and preventing insulating film breakdown when a high dV/dt during switching is applied. Furthermore, by forming the insulating film covering the shoulder portion, the sidewall portion, and the bottom portion, of the trench 40 of the gate pull-up portion simultaneously at the time of forming the field insulating film 20, the structure of the semiconductor device 100 according to the first preferred embodiment can be achieved without increasing the number of manufacturing steps and the manufacturing cost.

### Second Preferred Embodiment

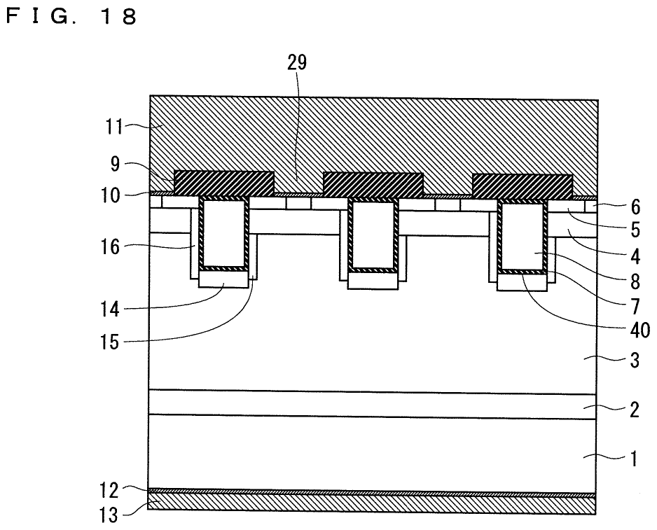

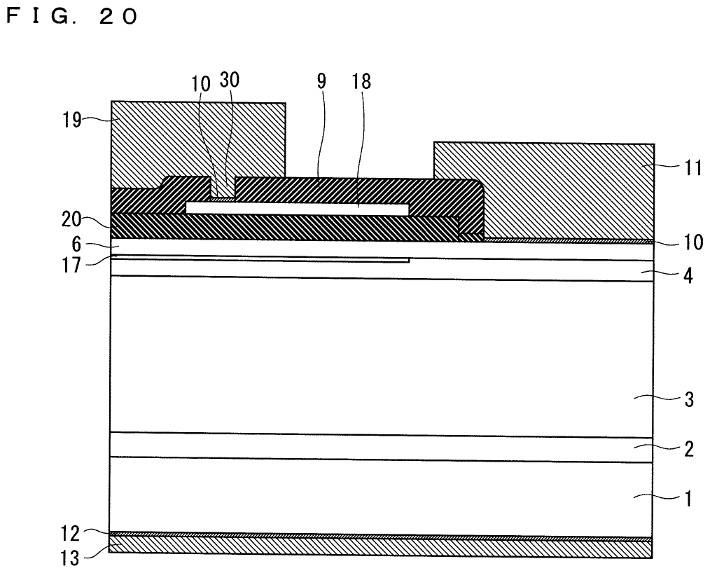

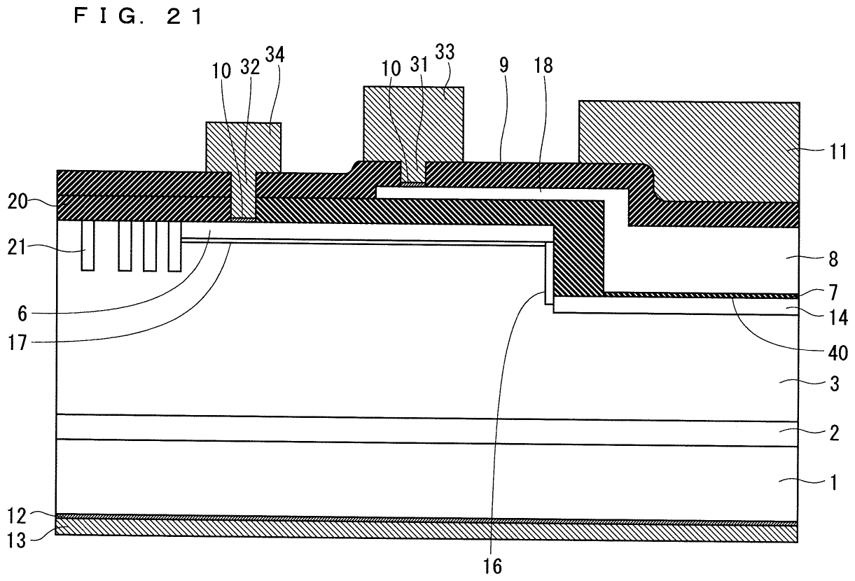

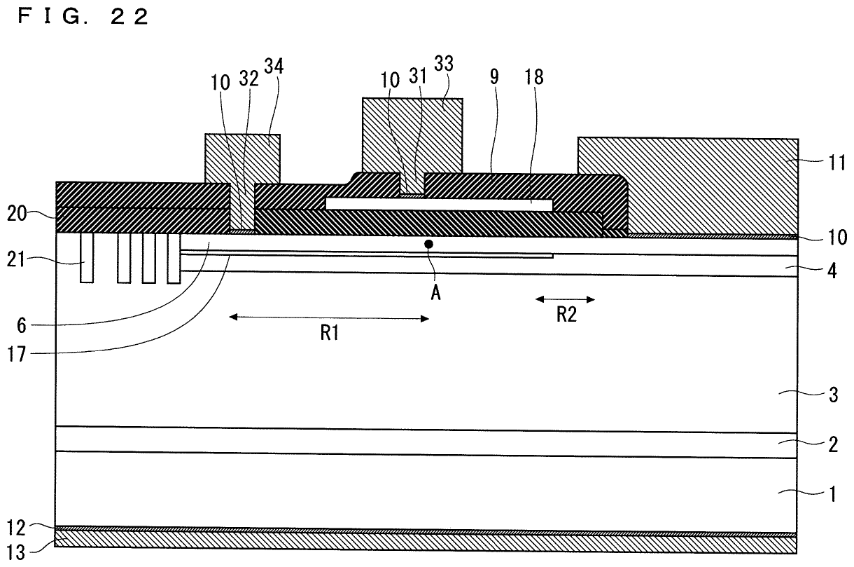

FIGS. 18 to 22 are views showing a configuration of a semiconductor device 100 according to a second preferred embodiment. FIGS. 18, 19, and 20 are cross-sectional views taken along lines A1-A2, B1-B2, and C1-C2 shown in FIG. 2, respectively. FIGS. 21 and 22 are cross-sectional views taken along lines D1-D2 and E1-E2 shown in FIG. 3, respectively. It should be noted that the cross-sectional configurations shown in FIGS. 18, 20, and 22 are similar to those shown in FIGS. 4, 6, and 8, respectively.

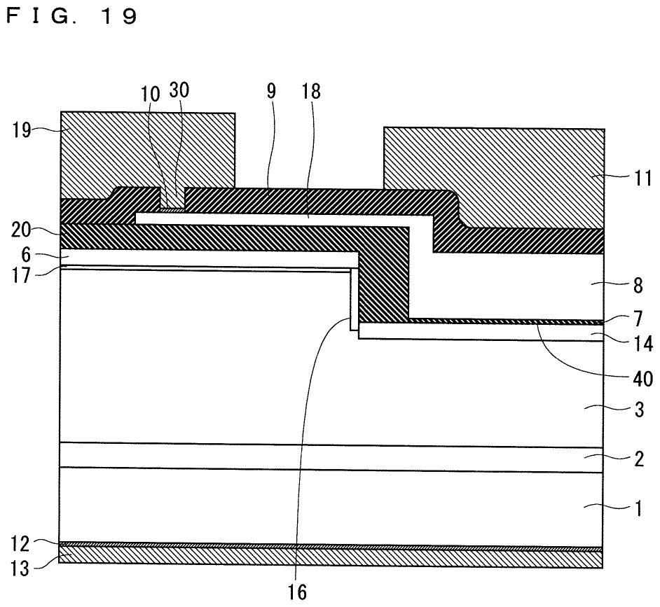

In the first preferred embodiment, the thickness of the field insulating film 20 covering the shoulder portion, the sidewall portion, and the bottom portion, of the trench 40 at the gate pull-up portion is equivalent to the thickness of the field insulating film 20 under the gate pad 19. On the other hand, in the second preferred embodiment, as shown in FIGS. 19 and 21, the thickness of the field insulating film 20 covering the shoulder portion, the sidewall portion, and the bottom portion, of the trench 40 at the gate pull-up portion is larger than the thickness of the field insulating film 20 under the gate pad 19. In addition, the field insulating film 20 formed on the gate pull-up portion has a shape having no step on the upper surface in a cross-sectional view. That is, the upper surface of the field insulating film 20 is flat without the recess corresponding to the trench 40.

In addition, in the second preferred embodiment, in order to obtain the field insulating film 20 having the shape as described above, the field insulating film 20 is formed by deposition of a TEOS insulating film containing O₃ (ozone) or a spin on glass (SOG) method.

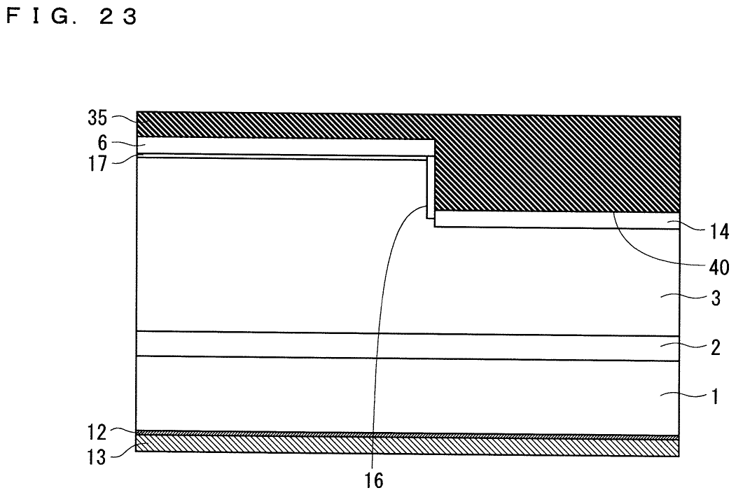

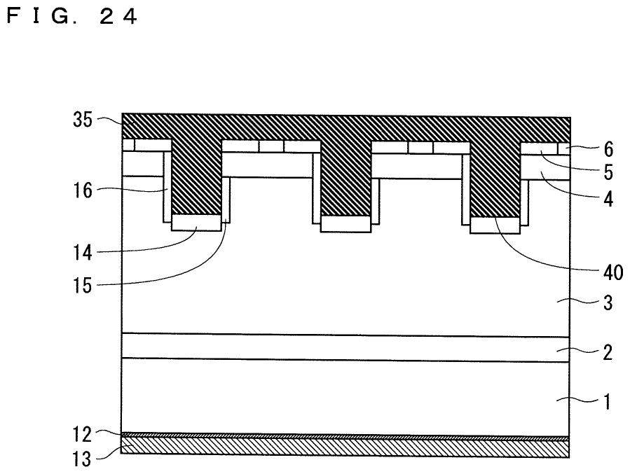

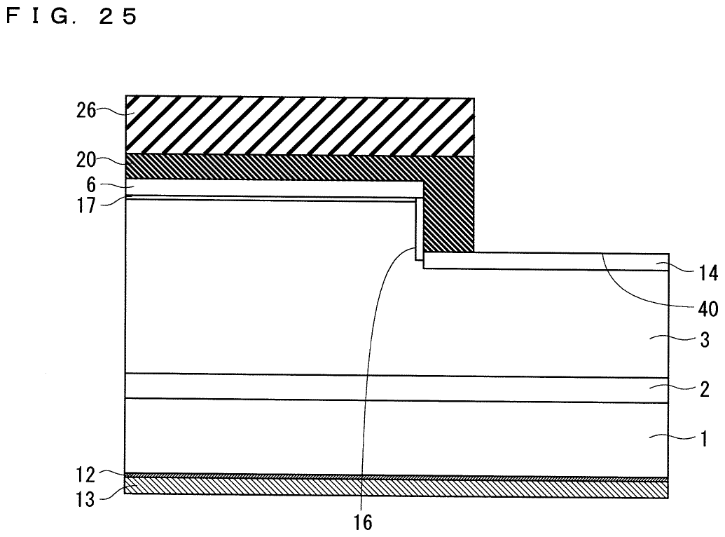

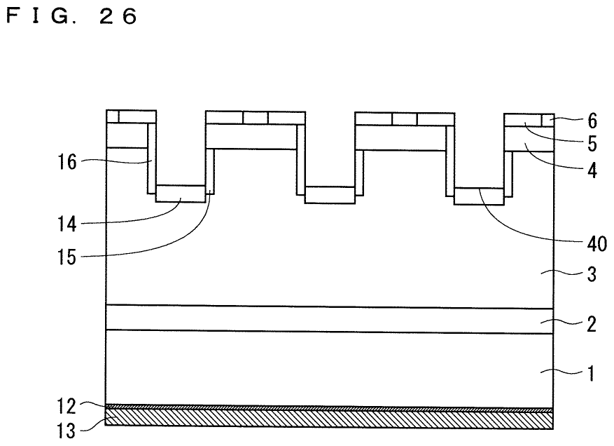

Next, a method of manufacturing the semiconductor device 100 according to the second preferred embodiment will be described. FIGS. 23 to 26 are explanatory diagrams of the manufacturing step of the semiconductor device 100 according to the second preferred embodiment. Among them, FIGS. 23 and 25 correspond to the cross section shown in FIG. 19 (cross section taken along line B1-B2 in FIG. 2), and FIGS. 24 and 26 correspond to the cross section shown in FIG. 18 (cross section taken along line A1-A2 in FIG. 2).

Since the steps up to the forming step of the field insulating film 20 are similar to the steps described with reference to FIGS. 9 to 13 in the first preferred embodiment, the description thereof is omitted here.

In the forming step of the field insulating film 20, first, the trench 40 is filled with the depositable insulating film 35 to be the material of the field insulating film 20 (FIGS. 23 and 24). As the depositable insulating film 35, an insulating material having high fluidity referred to as SOG or an insulating material having anisotropy in film formation such as a TEOS insulating film containing O₃ is used. Accordingly, the depositable insulating film 35 has a shape having no step on the upper surface in a cross-sectional view. That is, the upper surface of the depositable insulating film 35 is flat without the recess corresponding to the trench 40.

Subsequently, using a photolithography technique, a mask material 26 is formed so as to cover the withstand voltage holding region 102, the gate pad region 103, and the gate pull-up portion, and the field insulating film 20 is formed by etching the depositable insulating film 35 (FIGS. 25 and 26). Accordingly, the field insulating film 20 remains as an insulating film thicker than the gate insulating film 7 in the withstand voltage holding region 102, the gate pad region 103, and the gate pull-up portion. In addition, the field insulating film 20 is removed from a portion other than the gate pull-up portion in the trench 40.

Since the subsequent steps are similar to those in the first preferred embodiment, the description thereof is omitted.

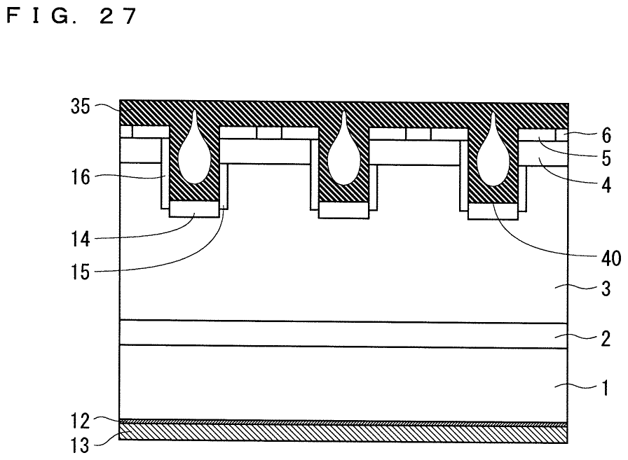

Parameters such as the thickness of the field insulating film 20 and the width and depth of the trench 40 are designed based on characteristics required of a product. Depending on a combination of these parameters, the trench 40 cannot be sufficiently filled with the depositable insulating film 35, and a cavity may be formed in the depositable insulating film 35 as shown in FIG. 27. In that case, there is a possibility that the field insulating film 20 having a sufficient thickness cannot be formed in the shoulder portion, the sidewall portion, and the bottom portion, of the trench 40 of the gate pull-up portion. In the present preferred embodiment, the reason why the depositable insulating film 35 is formed of a TEOS insulating film containing SOG or O₃ is to prevent this problem from occurring.

The SOG can be improved in fluidity and fillability by performing reflow after application. In addition, since the TEOS insulating film containing O₃ can reduce the amount of the depositable insulating film 35 deposited in the sidewall portion of the trench 40, formation of a cavity can be suppressed.

In addition, in the second preferred embodiment, the thickness of the field insulating film 20 covering the shoulder portion, the sidewall portion, and the bottom portion, of the trench 40 of the gate pull-up portion is determined by the position of the right end portion of the mask material 26 shown in FIG. 25, but the position of the mask material 26 may be shifted to the left and right. In addition, when the etching amount of the side surface of the depositable insulating film 35 has variations at the time of etching the depositable insulating film 35, the thickness of the field insulating film 20 covering the shoulder portion, the sidewall portion, and the bottom portion, of the trench 40 at the gate pull-up portion also varies. In consideration of these, the width and formation position of the mask material 26 are desirably designed so that the thickness of the field insulating film 20 covering the shoulder portion, the sidewall portion, and the bottom portion, of the trench 40 of the gate pull-up portion is equivalent to or larger than the thickness of the field insulating film 20 under the gate pad 19.

According to the semiconductor device 100 according to the second preferred embodiment, since the thickness of the field insulating film 20 covering the shoulder portion, the sidewall portion, and the bottom portion, of the trench 40 of the gate pull-up portion can be made larger than that of the first preferred embodiment, the effect of preventing the insulating film breakdown in the gate pull-up portion is further improved.

### Third Preferred Embodiment

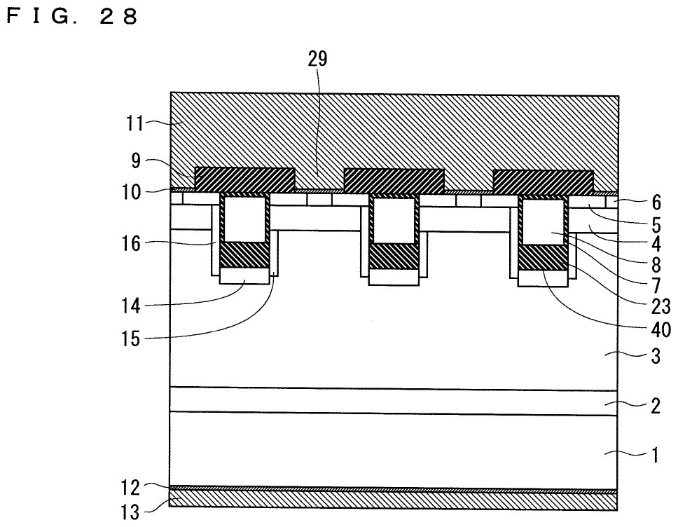

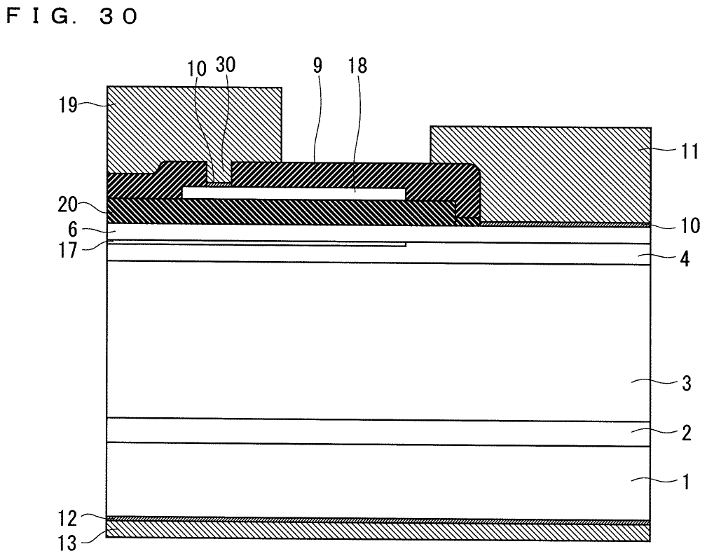

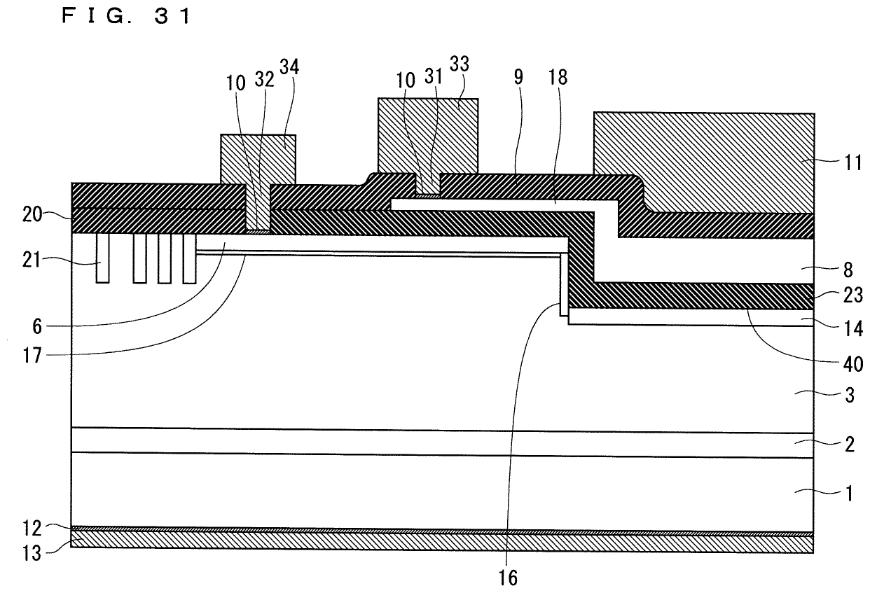

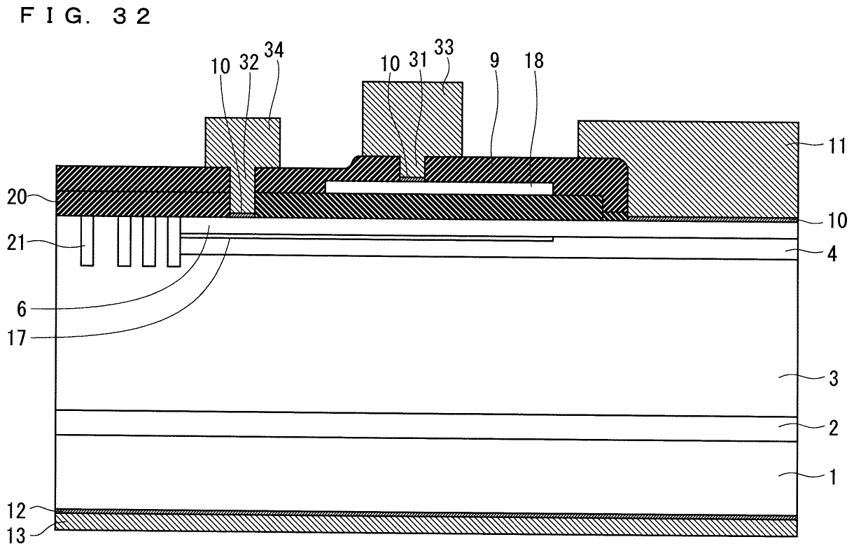

FIGS. 28 to 32 are views showing a configuration of a semiconductor device 100 according to a third preferred embodiment. FIGS. 28, 29, and 30 are cross-sectional views taken along lines A1-A2, B1-B2, and C1-C2 shown in FIG. 2, respectively. FIGS. 31 and 32 are cross-sectional views taken along lines D1-D2 and E1-E2 shown in FIG. 3, respectively. It should be noted that the cross-sectional configurations shown in FIGS. 30 and 32 are similar to those shown in FIGS. 6 and 8, respectively.

The semiconductor device 100 according to the third preferred embodiment has the following features in addition to the first to third features described in the first preferred embodiment. That is, as shown in FIGS. 28, 29, and 31, the semiconductor device 100 according to the third preferred embodiment includes a trench bottom portion insulating film 23 thicker than the gate insulating film 7 covering the sidewall portion of the trench 40 at the bottom portion of the trench 40 formed in the active region 101. The trench bottom portion insulating film 23 is equivalent to or greater than the thickness of the field insulating film 20 under the gate pad 19. In addition, the trench bottom portion insulating film 23 is formed simultaneously with the field insulating film 20 under the gate pad 19 (In other words, the trench bottom portion insulating film 23 is a part of the field insulating film 20).

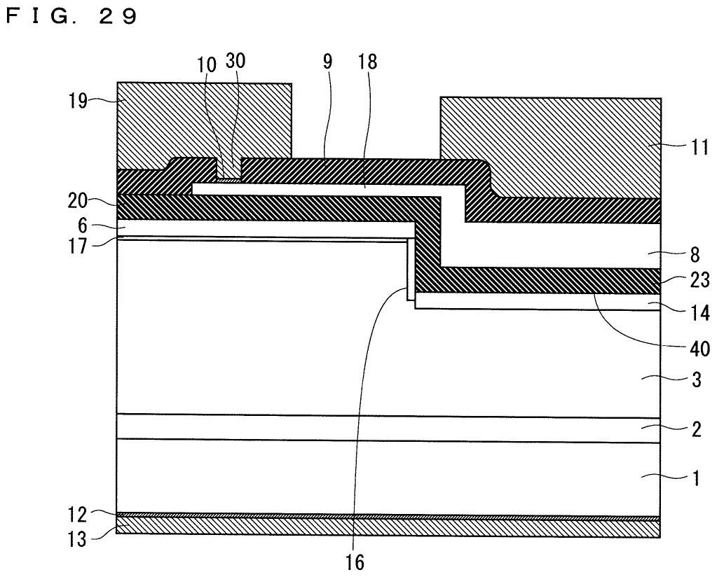

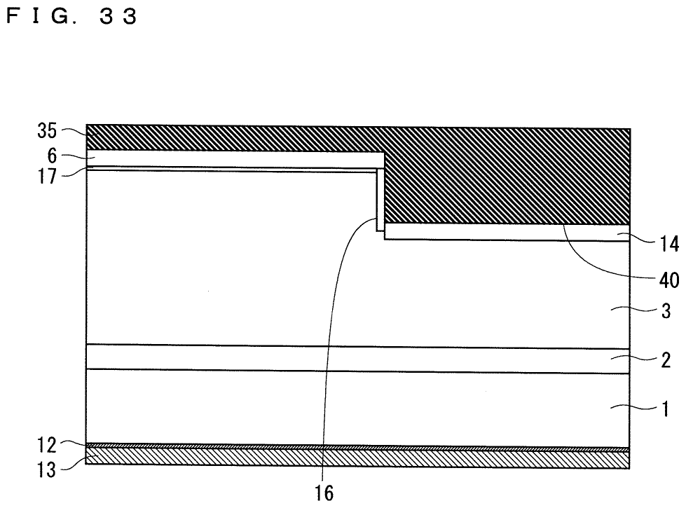

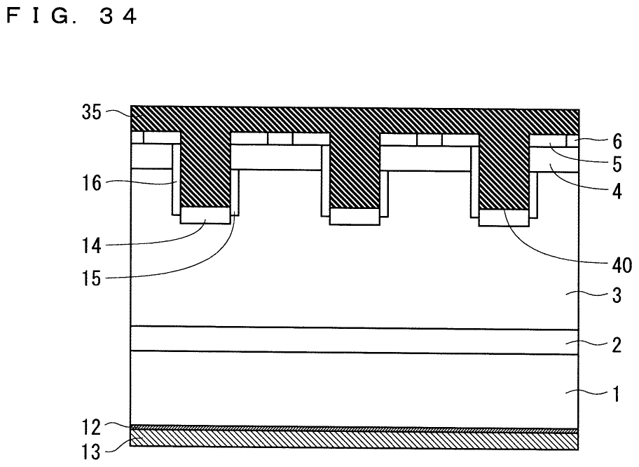

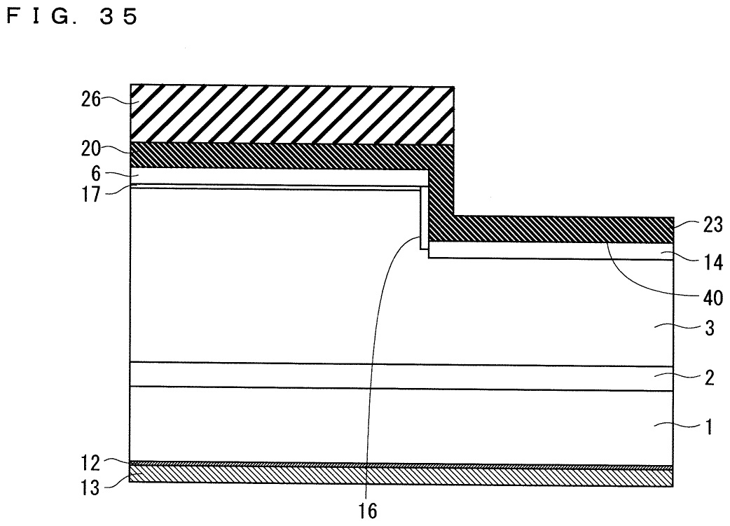

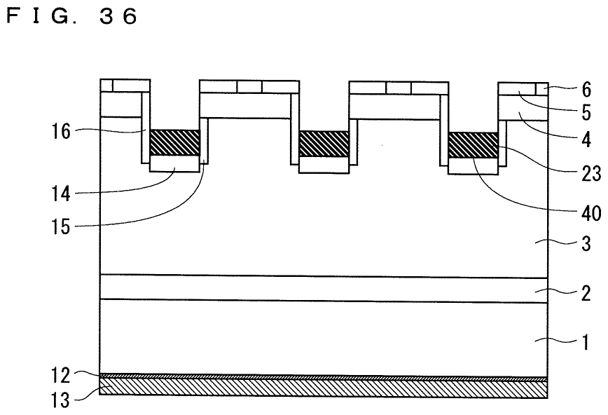

Next, a method of manufacturing the semiconductor device 100 according to the third preferred embodiment will be described. FIGS. 33 to 36 are explanatory diagrams of the manufacturing step of the semiconductor device 100 according to the third preferred embodiment. Among them, FIGS. 33 and 35 correspond to the cross section shown in FIG. 29 (cross section taken along line B1-B2 in FIG. 2), and FIGS. 34 and 36 correspond to the cross section shown in FIG. 28 (cross section taken along line A1-A2 in FIG. 2).

Since the steps up to the forming step of the field insulating film 20 are similar to the steps described with reference to FIGS. 9 to 13 in the first preferred embodiment, the description thereof is omitted here.

In the forming step of the field insulating film 20, first, as in the second preferred embodiment, the trench 40 is filled with the depositable insulating film 35 to be the material of the field insulating film 20 (FIGS. 33 and 34). As the depositable insulating film 35, an insulating material having high fluidity referred to as SOG or an insulating material having anisotropy in film formation such as a TEOS insulating film containing O₃ is used.

Subsequently, using a photolithography technique, a mask material 26 is formed so as to cover the withstand voltage holding region 102, the gate pad region 103, and the gate pull-up portion, and the field insulating film 20 is formed by etching the depositable insulating film 35 (FIGS. 35 and 36). However, in this step, as shown in FIGS. 35 and 36, the etching of the depositable insulating film 35 is stopped halfway (before reaching the bottom portion of the trench 40), and the depositable insulating film 35 is left at the bottom portion of the trench 40 in the active region 101, whereby the trench bottom portion insulating film 23 is formed.

Since the subsequent steps are similar to those in the first preferred embodiment, the description thereof is omitted.

In the semiconductor device 100 according to the third preferred embodiment, since a thick trench bottom portion insulating film 23 is formed at the bottom portion of the trench 40, the capacitance (feedback capacitance) between the drain electrode 13 and the gate electrode 8 is significantly reduced. Therefore, effects can be obtained that gate drive can be performed with less electric charge and high-speed switching is enabled. In addition, effects similar to those of the first preferred embodiment can be obtained.

### Fourth Preferred Embodiment

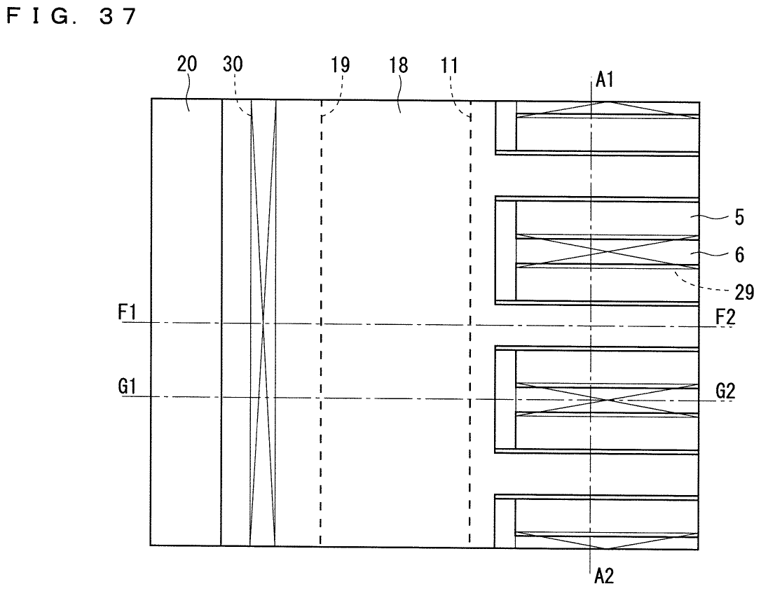

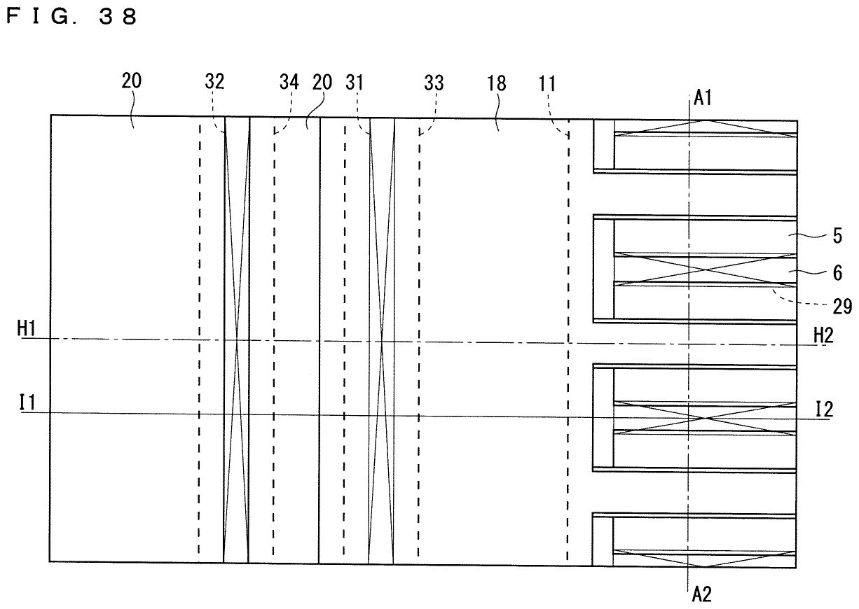

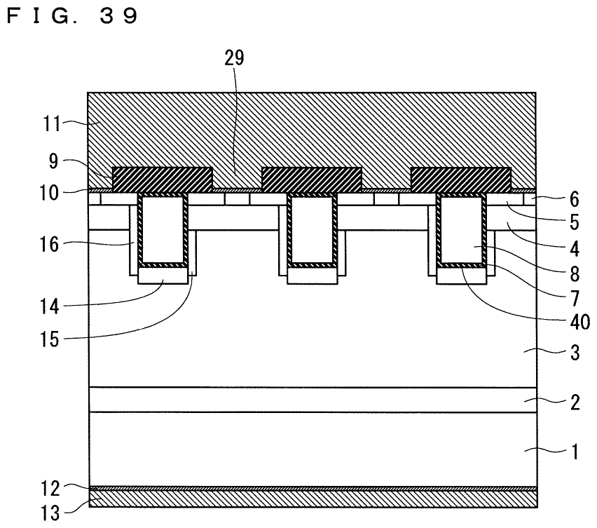

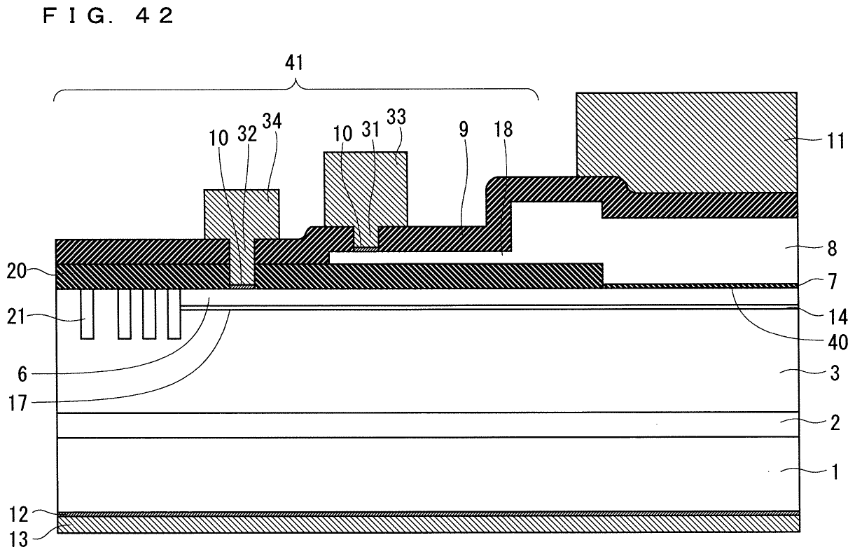

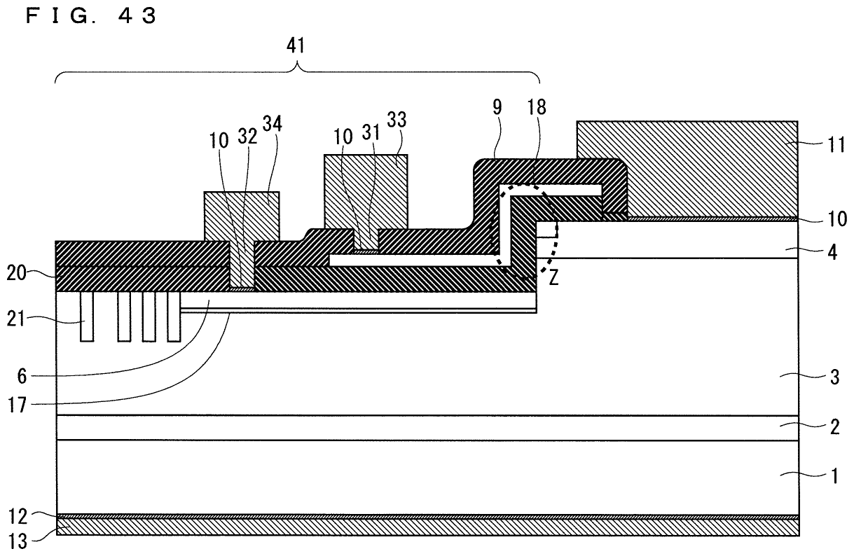

FIGS. 37 to 43 are views showing a configuration of a semiconductor device 100 according to a fourth preferred embodiment. FIG. 37 is an enlarged plan view of a boundary portion 104 between the active region 101 and the gate pad region 103 shown in FIG. 1, and FIG. 38 is an enlarged plan view of a boundary portion 106 between the active region 101 and the withstand voltage holding region 102 shown in FIG. 1. In addition, FIGS. 39, 40, and 41 are cross-sectional views taken along lines A1-A2, F1-F2, and G1-G2 shown in FIG. 37, respectively. FIGS. 42 and 43 are cross-sectional views taken along lines H1-H2 and I1-I2 shown in FIG. 38, respectively. It should be noted that the cross-sectional configurations shown in FIGS. 30 and 32 are similar to those shown in FIGS. 6 and 8, respectively. It should be noted that the cross-sectional configuration shown in FIG. 39 is similar to that shown in FIG. 4.

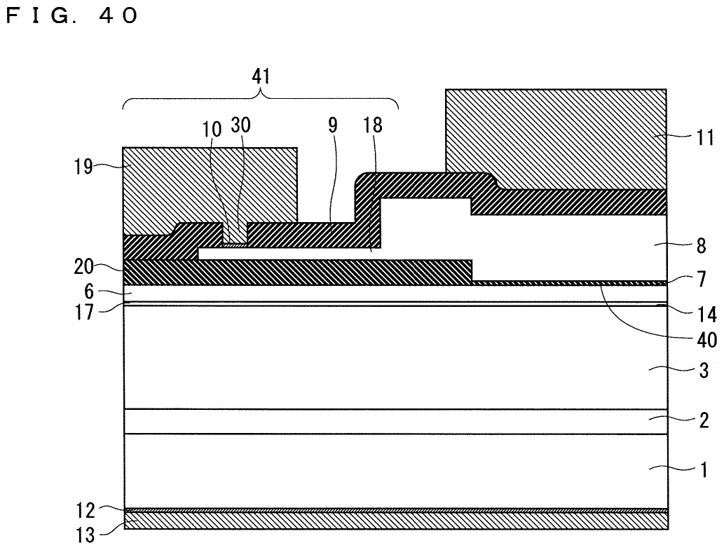

In the semiconductor device 100 according to the fourth preferred embodiment, as shown in FIGS. 40 to 43, an outer peripheral trench 41 which is a trench having a depth equivalent to that of the trench 40 is formed in the withstand voltage holding region 102 and the gate pad region 103 outside the active region 101. In the present preferred embodiment, the gate pad 19, the outer peripheral gate wiring line 33, and the outer peripheral source wiring line 34 disposed in the withstand voltage holding region 102 and the gate pad region 103, and the gate lead-out wiring line 18, the interlayer insulating film 9, the field insulating film 20, and the like provided under these are formed in the outer peripheral trench 41.

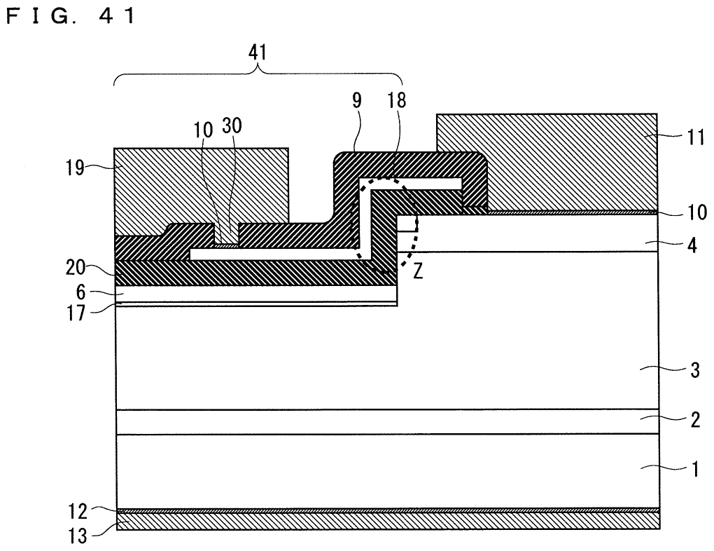

As shown in FIGS. 40 and 42, the trench 40 in the active region 101 extends to the withstand voltage holding region 102 and is connected to the outer peripheral trench 41. Therefore, the trench shoulder portion in the gate pull-up portion becomes a boundary portion (region Z shown in FIGS. 41 and 43) between the mesa-shaped semiconductor layer between the trenches 40 and the outer peripheral trench 41. In the fourth preferred embodiment, the shoulder portion, the sidewall portion, and the bottom portion, of this portion are covered with an insulating film having a thickness equivalent to or larger than that of the field insulating film 20 under the gate pad 19.

It should be noted that the semiconductor device 100 according to the fourth preferred embodiment can be formed by changing a mask pattern of photolithography by a manufacturing method similar to that of the first preferred embodiment.

Due to the structure, a step corresponding to the depth of the trench 40 is generated between the surface of the semiconductor layer and the bottom portion of the trench 40. Therefore, a large voltage is likely to be applied to the end portion of the trench 40 on the side of the withstand voltage holding region 102. As a countermeasure against this, there is a technique of forming a p-type diffusion layer deeper than the trench 40 in the withstand voltage holding region 102 so as to be adjacent to the sidewall portion and the bottom end portion of the trench 40, thereby alleviating the electric field generated at the end portion of the trench 40.

However, when the semiconductor layer is made of a material having a small impurity diffusion coefficient such as silicon carbide (SiC), it is difficult to form a p-type diffusion layer deeper than the trench 40 in the withstand voltage holding region 102. Therefore, in the present preferred embodiment, an outer peripheral trench 41 having the same depth as the trench 40 of the active region 101 is provided in the withstand voltage holding region 102 and the gate pad region 103, thereby eliminating the step between the surface of the semiconductor layer of the withstand voltage holding region 102 and the gate pad region 103 and the bottom portion of the trench 40. By providing a p-type diffusion layer such as the trench bottom portion p-type layer 14 or the under gate pad p-type layer 17 at the bottom portion of the outer peripheral trench 41, the electric field generated at the end portion of the trench 40 can be alleviated. With this, it is possible to achieve stabilization of the withstand voltage of the semiconductor device 100, suppression of insulating film breakdown at the end portion of the trench 40, and the like. Therefore, the fourth preferred embodiment is particularly effective when the semiconductor layer is made of a material having a small impurity diffusion coefficient such as SiC.

### Fifth Preferred Embodiment

The present preferred embodiment is obtained by applying the semiconductor device according to the above-described first to fourth preferred embodiments to a power conversion apparatus. Application of the semiconductor device according to the first to fourth preferred embodiments is not limited to a specific power conversion apparatus, and hereinafter, a case where the semiconductor device according to the first to fourth preferred embodiments is applied to a three-phase inverter will be described below as a fifth preferred embodiment.

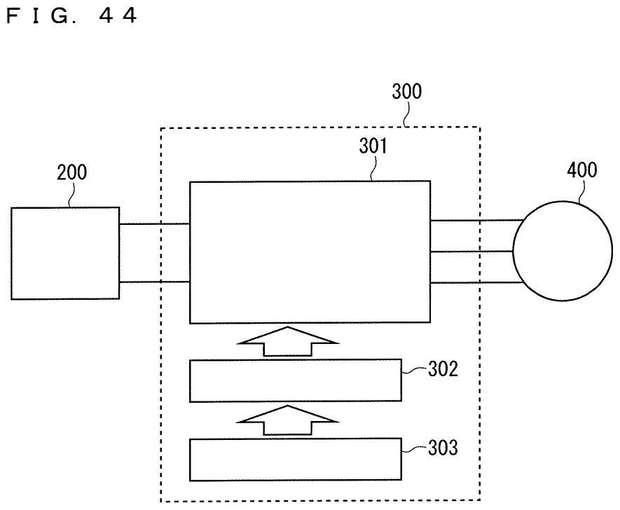

FIG. 44 is a block diagram showing a configuration of a power conversion system to which the power conversion apparatus according to the present preferred embodiment is applied.

The power conversion system shown in FIG. 44 includes a power supply 200, a power conversion apparatus 300, and a load 400. The power supply 200 is a DC power supply, and supplies DC power to the power conversion apparatus 300. The power supply 200 can include various components, can include, for example, a DC system, a solar cell, and a storage battery, and may include a rectifier circuit or an AC/DC converter connected to an AC system. In addition, the power supply 200 may include a DC/DC converter for converting DC power output from the DC system into predetermined power.

The power conversion apparatus 300 is a three-phase inverter connected between the power supply 200 and the load 400, converts DC power supplied from the power supply 200 into AC power, and supplies AC power to the load 400. As shown in FIG. 44, the power conversion apparatus 300 includes a main conversion circuit 301 for converting DC power into AC power to output the converted power, a drive circuit 302 for outputting a drive signal for driving each switching element of the main conversion circuit 301, and a control circuit 303 for outputting a control signal for controlling the drive circuit 302 to the drive circuit 302.

The load 400 is a three-phase electric motor driven by AC power supplied from the power conversion apparatus 300. It should be noted that the load 400 is not limited to a specific application, and is a motor mounted on various electric apparatuses, and is used as, for example, a hybrid vehicle, an electric vehicle, a railway vehicle, an elevator, or a motor for an air conditioner.

Hereinafter, details of the power conversion apparatus 300 will be described. The main conversion circuit 301 includes a switching element and a freewheeling diode (not shown), and switching of the switching element converts the DC power supplied from the power supply 200 into AC power to supply the AC power to the load 400. There are various specific circuit configurations of the main conversion circuit 301, and the main conversion circuit 301 according to the present preferred embodiment is a two-level three-phase full bridge circuit and can include six switching elements and six freewheeling diodes antiparallel to the respective switching elements. A semiconductor device according to any one of the above-described first to fourth preferred embodiments is applied to each switching element of the main conversion circuit 301. The six switching elements are connected in series for every two switching elements to constitute upper and lower arms, and the respective upper and lower arms constitute each phase (U phase, V phase, and W phase) of the full bridge circuit. Then, the output terminals of the respective upper and lower arms, that is, the three output terminals of the main conversion circuit 301 are connected to the load 400.

The drive circuit 302 generates drive signals for driving the switching elements of the main conversion circuit 301, and supplies the drive signals to the control electrodes of the switching elements of the main conversion circuit 301. Specifically, in accordance with a control signal from a control circuit 303 described below, a drive signal to turn on the switching element and a drive signal to turn off the switching element are output to the control electrodes of the respective switching elements. When the switching element is maintained in the ON state, the drive signal is a voltage signal not less than the threshold voltage of the switching element (ON signal), and when the switching element is maintained in the OFF state, the drive signal is a voltage signal not more than the threshold voltage of the switching element (OFF signal).

The control circuit 303 controls the switching elements of the main conversion circuit 301 so that desired power is supplied to the load 400. Specifically, based on the power to be supplied to the load 400, the time required for each switching element of the main conversion circuit 301 to be turned on (ON time) is calculated. For example, the main conversion circuit 301 can be controlled by PWM control for modulating the ON time of the switching element according to the voltage to be output. Then, a control instruction (control signal) is output to the drive circuit 302 so that, at each time point, the ON signal is output to the switching element to be turned on and the OFF signal is output to the switching element to be turned off. The drive circuit 302 outputs the ON signal or OFF signal as a drive signal to the control electrode of each switching element in accordance with the control signal.

In the power conversion apparatus according to the present preferred embodiment, since the semiconductor device according to the first to fourth preferred embodiments is applied as the switching element of the main conversion circuit 301, it is possible to improve the withstand voltage performance.

In the present preferred embodiment, an example in which the semiconductor device according to the first to fourth preferred embodiments is applied to the two-level three-phase inverter has been described, but the application of the semiconductor device according to the first to fourth preferred embodiments is not limited thereto, and can be applied to various power conversion apparatuses. In the present preferred embodiment, a two-level power conversion apparatus is used, but a three-level or multilevel power conversion apparatus may be used, and when power is supplied to a single-phase load, the semiconductor device according to the first to fourth preferred embodiments may be applied to a single-phase inverter. In addition, when power is supplied to a DC load or the like, the semiconductor device according to the first to fourth preferred embodiments can also be applied to a DC/DC converter or an AC/DC converter.

In addition, the power conversion apparatus to which the semiconductor device according to the first to fourth preferred embodiments is applied is not limited to the case where the load described above is a motor, and can also be used as a power supply device for, for example, an electrical discharge machine, a laser machine, an induction heating cooker, or a non-contact feeding system, and furthermore, can also be used as a power conditioner of a solar power generation system, a storage system, or the like.

It should be noted that each preferred embodiment can be freely combined, and each preferred embodiment can be appropriately modified or omitted.

### APPENDIXES

Hereinafter, various aspects of the present disclosure will be collectively described as appendixes.

### Appendix 1

A semiconductor device comprising:
a semiconductor layer in which an active region in which a semiconductor element is formed and a withstand voltage holding region outside the active region are defined;
a trench formed in the semiconductor layer in the active region;
a gate insulating film formed on an inner surface of the trench;
a gate electrode provided on the gate insulating film and embedded in the trench;
a field insulating film formed on the semiconductor layer, the field insulating film thicker than the gate insulating film;
a gate pad formed on the field insulating film; and
a gate lead-out wiring line connecting the gate pad and the gate electrode,
wherein in a gate pull-up portion being an end portion of the trench corresponding to a place where the gate lead-out wiring line and the gate electrode in the trench are connected, a shoulder portion, a sidewall portion, and a bottom portion of the trench are covered with the field insulating film, and the gate lead-out wiring line is formed on the field insulating film, and
wherein in the gate pull-up portion, a thickness of the field insulating film covering the shoulder portion, the sidewall portion, and the bottom portion of the trench is equivalent to or larger than a thickness of the field insulating film under the gate pad.

### Appendix 2

The semiconductor device according to Appendix 1,
wherein a trench bottom portion insulating film thicker than the gate insulating film covering the sidewall portion of the trench is formed at the bottom portion of the trench formed in the active region, and
wherein a thickness of the trench bottom portion insulating film is equivalent to or greater than a thickness of the field insulating film under the gate pad.

### Appendix 3

The semiconductor device according to Appendix 1 or 2, wherein the field insulating film formed on the gate pull-up portion has a stepped shape with a step on an upper surface in a cross-sectional view.

### Appendix 4

The semiconductor device according to Appendix 1 or 2, wherein the field insulating film formed on the gate pull-up portion has a shape without a step on an upper surface in a cross-sectional view.

### Appendix 5

The semiconductor device according to any one of Appendixes 1 to 4,
wherein an outer peripheral trench having a depth equivalent to that of the trench is formed in the withstand voltage holding region, and
wherein the trench extends to the withstand voltage holding region and is connected to the outer peripheral trench.

### Appendix 6

The semiconductor device according to any one of Appendixes 1 to 5,
further comprising:
a main electrode of the semiconductor element formed on the semiconductor layer,
a drift layer of a first conductivity type formed in the semiconductor layer, and
an impurity diffusion layer of a second conductivity type formed in a surface portion of the drift layer and electrically connected to the main electrode, and
wherein when a resistance value between a point farthest from a contact place of the main electrode to which a potential of the main electrode is applied in the impurity diffusion layer under the gate pad and the contact place of the main electrode is R1, and a resistance value between an end portion of the impurity diffusion layer under the trench of the gate pull-up portion and the contact place of the main electrode is R2, R1≥R2 holds.

### Appendix 7

A power conversion apparatus comprising:
a main conversion circuit including a semiconductor device according to any one of Appendixes 1 to 6, the main conversion circuit configured to convert power to be input to output the converted power;
a drive circuit configured to output to the semiconductor device a drive signal for driving the semiconductor device; and
a control circuit configured to output to the drive circuit a control signal for controlling the drive circuit.

### Appendix 8

A method of manufacturing the semiconductor device according to any one of Appendixes 1 to 6, the method comprising simultaneously forming the field insulating film covering the shoulder portion, the sidewall portion, and the bottom portion of the trench in the gate pull-up portion and the field insulating film under the gate pad.

### Appendix 9

The method of manufacturing the semiconductor device according to Appendix 8, wherein the field insulating film is formed by depositing a TEOS insulating film containing O₃.

### Appendix 10

The method of manufacturing the semiconductor device according to Appendix 8, wherein the field insulating film is formed by a spin on glass (SOG) method.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor layer in which an active region in which a semiconductor element is formed and a withstand voltage holding region outside the active region are defined;
a trench formed in the semiconductor layer in the active region;
a gate insulating film formed on an inner surface of the trench;
a gate electrode provided on the gate insulating film and embedded in the trench;
a field insulating film formed on the semiconductor layer, the field insulating film thicker than the gate insulating film;
a gate pad formed on the field insulating film; and
a gate lead-out wiring line connecting the gate pad and the gate electrode,
wherein in a gate pull-up portion being an end portion of the trench corresponding to a place where the gate lead-out wiring line and the gate electrode in the trench are connected, a shoulder portion, a sidewall portion, and a bottom portion of the trench are covered with the field insulating film, and the gate lead-out wiring line is formed on the field insulating film, and
wherein in the gate pull-up portion, a thickness of the field insulating film covering the shoulder portion, the sidewall portion, and the bottom portion of the trench is equivalent to or larger than a thickness of the field insulating film under the gate pad.

2. The semiconductor device according to claim 1,
wherein a trench bottom portion insulating film thicker than the gate insulating film covering the sidewall portion of the trench is formed at the bottom portion of the trench formed in the active region, and
wherein a thickness of the trench bottom portion insulating film is equivalent to or greater than a thickness of the field insulating film under the gate pad.

3. The semiconductor device according to claim 1, wherein the field insulating film formed on the gate pull-up portion has a stepped shape with a step on an upper surface in a cross-sectional view.

4. The semiconductor device according to claim 1, wherein the field insulating film formed on the gate pull-up portion has a shape without a step on an upper surface in a cross-sectional view.

5. The semiconductor device according to claim 1,
wherein an outer peripheral trench having a depth equivalent to that of the trench is formed in the withstand voltage holding region, and
wherein the trench extends to the withstand voltage holding region and is connected to the outer peripheral trench.

6. The semiconductor device according to any one of claim 1,
further comprising:
a main electrode of the semiconductor element formed on the semiconductor layer,
a drift layer of a first conductivity type formed in the semiconductor layer, and
an impurity diffusion layer of a second conductivity type formed in a surface portion of the drift layer and electrically connected to the main electrode, and
wherein when a resistance value between a point farthest from a contact place of the main electrode to which a potential of the main electrode is applied in the impurity diffusion layer under the gate pad and the contact place of the main electrode is R1, and a resistance value between an end portion of the impurity diffusion layer under the trench of the gate pull-up portion and the contact place of the main electrode is R2, R1≥R2 holds.

7. A power conversion apparatus comprising:
a main conversion circuit including the semiconductor device according to claim 1, the main conversion circuit configured to convert power to be input to output the converted power;
a drive circuit configured to output to the semiconductor device a drive signal for driving the semiconductor device; and
a control circuit configured to output to the drive circuit a control signal for controlling the drive circuit.

8. A method of manufacturing the semiconductor device according to claim 1, the method comprising simultaneously forming the field insulating film covering the shoulder portion, the sidewall portion, and the bottom portion of the trench in the gate pull-up portion and the field insulating film under the gate pad.

9. The method of manufacturing the semiconductor device according to claim 8, wherein the field insulating film is formed by depositing a TEOS insulating film containing O₃.

10. The method of manufacturing the semiconductor device according to claim 8, wherein the field insulating film is formed by a spin on glass (SOG) method.
